(19) United States
(12) Patent Application Publication
(10) Pub. No.: US 2026/0182139 A1
(43) Pub. Date: Jun. 25, 2026

(54) LIGHT-EMITTING DEVICE AND PREPARATION METHOD THEREOF, DISPLAY DEVICE

(71) Applicant: BOE Technology Group Co., Ltd., Beijing (CN)

(72) Inventors: Shuaifeng Zhang, Beijing (CN); Haiyan Sun, Beijing (CN); Xiaojin Zhang, Beijing (CN); Dan Wang, Beijing (CN)

(21) Appl. No.: 18/834,743

(22) PCT Filed: Apr. 26, 2023
(86) PCT No.: PCT/CN2023/090883

§ 371 Date: Jul. 31, 2024

(51) Int. Cl. H10K 50/155; H10K 50/115; H10K 50/16; H10K 85/60; H10K 101/30

(52) U.S. Cl. CPC H10K 50/155; H10K 50/115; H10K 50/16; H10K 85/622; H10K 2101/30

(57) ABSTRACT

The present disclosure provides a light-emitting device, a manufacturing method thereof, and a display device. The light-emitting device includes a composite hole transport layer. The composite hole transport layer includes a matrix and a discoidal liquid crystal component. The hole mobility of the discotic liquid crystal component is greater than the hole mobility of the matrix.

### TECHNICAL FIELD

The present disclosure relates to the field of display technology, and in particular, to a light-emitting device, a preparation method thereof, and a display device.

### BACKGROUND

Light-Emitting Diode (LED) emits light by releasing energy through the recombination of electrons and holes. Light-emitting diodes comprise, but are not limited to, organic light-emitting diodes (OLED) and quantum dot light-emitting diodes (QLED). Quantum dots have great application potential in high color quality displays due to their many advantages such as high quantum efficiency, narrow excitation spectrum, high photostability, long fluorescence lifetime, and good solution processing compatibility. Quantum dot light-emitting technology has become the most promising next-generation self-light-emitting display technology.

### SUMMARY

According to an aspect of the present disclosure, a light-emitting device is provided. The light-emitting device comprises a composite hole transport layer, wherein the composite hole transport layer comprises a matrix and a discotic liquid crystal composition, a hole mobility of the discotic liquid crystal composition is greater than a hole mobility of the matrix.

In some embodiments, a hole mobility of the composite hole transport layer is 10⁻⁴˜10⁻³ cm²V⁻¹s⁻¹.

In some embodiments, an energy level of a highest occupied molecular orbital of the composite hole transport layer is −6.0˜−5.3 eV.

In some embodiments, a mass proportion of the discotic liquid crystal composition in the composite hole transport layer is 1%˜40%.

In some embodiments, the mass proportion of the discotic liquid crystal composition in the composite hole transport layer is 20%.

In some embodiments, a general structural formula of the composite hole transport layer is:

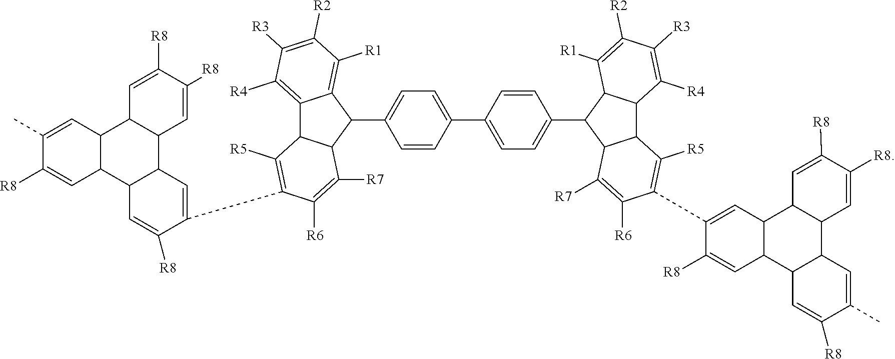

R8 comprises any one of an alkyl chain, an alkoxy chain, and an alkyl ester chain, R8 at different positions of the general structural formula of the composite hole transport layer are same or different, and each of R1 to R7 comprises any one of a benzene ring, a double bond, a cyclohexane, and a hydrogen atom.

In some embodiments, the discotic liquid crystal composition is formed from discotic liquid crystal monomers, and a general structural formula of the discotic liquid crystal monomers is:

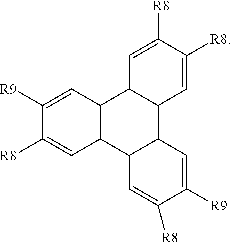

R9 is a polymerizable functional group and comprises any one of a tert-butyl ethyl ester, an olefinic bond, an acrylate, a vinyl ether, a thiol, and an epoxy.

In some embodiments, R8 is a flexible alkyl chain having 4˜6 carbon atoms.

In some embodiments, R8 is any one of a butoxy, a pentyloxy, a hexyloxy, a butyl ester group, an amyl ester group, and a hexyl ester group.

In some embodiments, the matrix is configured to cause holes to migrate in an orderly manner in the composite hole transport layer under an action of an electric field.

In some embodiments, the matrix is formed of matrix monomers, and a general structural formula of the matrix monomers is:

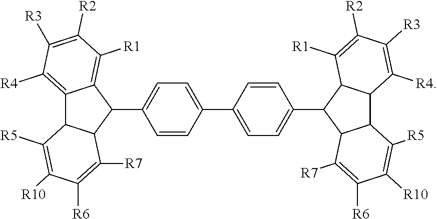

R10 is a polymerizable functional group and comprises any one of an olefinic bond, an acrylate, a vinyl ether, a thiol, and an epoxy.

In some embodiments, each of R1 to R7 is a hydrogen atom, R10 is the olefinic bond, R8 is an alkoxy chain, and R9 is a tert-butyl ethyl ester.

In some embodiments, at least one of R9 and R10 is an ultraviolet polymerizable functional group, and the ultraviolet polymerizable functional group comprises at least a difunctional monomer.

In some embodiments, at least one of R9 and R10 is a thermally polymerizable functional group, and the thermally polymerizable functional group comprises at least a difunctional monomer.

In some embodiments, the discotic liquid crystal compositions are arranged as columnar structures in an ordered manner in the composite hole transport layer, a height direction of a respective one of the columnar structures is parallel to a thickness direction of the composite hole transport layer, and the matrix is at least arranged among the columnar structures.

In some embodiments, the hole mobility of the discotic liquid crystal composition is 10⁻³˜10⁻² cm²V⁻¹s⁻¹.

In some embodiments, an energy level of a highest occupied molecular orbital of the discotic liquid crystal composition is −6.5˜−5.5 eV, and an energy level of a lowest unoccupied molecular orbital of the discotic liquid crystal composition is −3.0˜−1.8 eV.

In some embodiments, the light-emitting device further comprises a first electrode layer; a hole injection layer between the first electrode layer and the composite hole transport layer; a light-emitting layer on a side of the composite hole transport layer away from the first electrode layer; an electron transport layer on a side of the light-emitting layer away from the first electrode layer; an electron injection layer on a side of the electron transport layer away from the first electrode layer; and a second electrode layer on a side of the electron injection layer away from the first electrode layer.

In some embodiments, the light-emitting layer comprises a quantum dot configured to emit blue light.

In some embodiments, a material of the first electrode layer is indium tin oxide, a material of the hole injection layer is poly(3,4-ethylenedioxythiophene): polystyrene sulfonate, a material of the electron transport layer is zinc oxide, a material of the electron injection layer is polyvinylpyrrolidone, a material of the second electrode layer is aluminum, a wavelength of the blue light emitted by the light-emitting layer is 455˜465 nm, a mass proportion of the discotic liquid crystal composition in the composite hole transport layer is 20%, a mass proportion of the matrix in the composite hole transport layer is 80%, and a structural formula of the composite hole transport layer is:

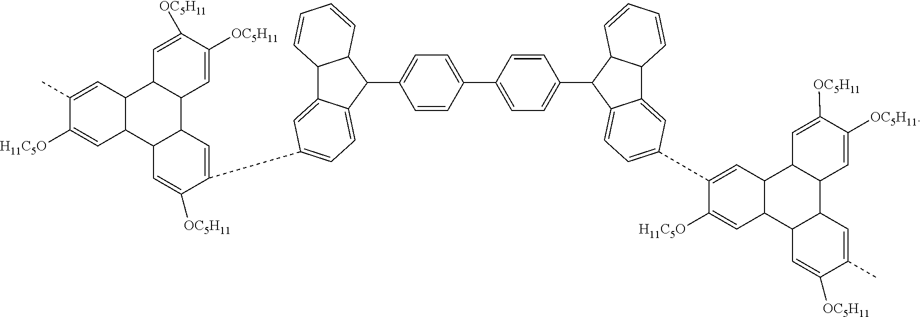

In some embodiments, the light-emitting layer comprises a quantum dot configured to emit red light, a mass proportion of the discotic liquid crystal composition in the composite hole transport layer is 25%˜30%, and a wavelength of the red light is 620˜640 nm.

In some embodiments, the light-emitting layer comprises a quantum dot configured to emit green light, a mass proportion of the discotic liquid crystal composition in the composite hole transport layer is 20%˜25%, and a wavelength of the green light is 525˜535 nm.

According to another aspect of the present disclosure, a display device is provided, which comprises a plurality of light-emitting devices described in any of the previous embodiments.

According to yet another aspect of the present disclosure, a method of preparing a light-emitting device is provided, comprising: providing a mixed solution comprising matrix monomers and discotic liquid crystal monomers; removing a solvent of the mixed solution and performing an annealing treatment to allow the discotic liquid crystal monomers to self-assemble; and polymerizing the matrix monomer and a self-assembled discotic liquid crystal monomers to form a composite hole transport layer comprising a matrix and a discotic liquid crystal composition, a hole mobility of the discotic liquid crystal composition being greater than a hole mobility of the matrix.

In some embodiments, the removing the solvent of the mixed solution and performing the annealing treatment to allow the discotic liquid crystal monomers to self-assemble, comprises: self-assembling the discotic liquid crystal monomers to form columnar structures that are arranged in an ordered manner and embedded in the matrix monomer, a height direction of a respective one of the columnar structures is parallel to a thickness direction of the composite hole transport layer.

In some embodiments, the polymerizing the matrix monomers and the self-assembled discotic liquid crystal monomers to form the composite hole transport layer comprising the matrix and the discotic liquid crystal composition, comprises: irradiating the matrix monomers and the self-assembled discotic liquid crystal monomers with ultraviolet light, to make the matrix monomer and the self-assembled discotic liquid crystal monomers undergo ultraviolet polymerization to form the composite hole transport layer.

In some embodiments, the polymerizing the matrix monomers and the self-assembled discotic liquid crystal monomers to form the composite hole transport layer comprising the matrix and the discotic liquid crystal composition, comprises: heating the matrix monomers and the self-assembled discotic liquid crystal monomers to make the matrix monomer and the self-assembled discotic liquid crystal monomers undergo thermal polymerization to form the composite hole transport layer.

In some embodiments, the providing the mixed solution comprising the matrix monomers and the discotic liquid crystal monomers, comprises: dissolving the matrix monomers and the discotic liquid crystal monomers in a toluene solvent at a mass ratio of 8:2 to form the mixed solution; the removing the solvent of the mixed solution and performing the annealing treatment to allow the discotic liquid crystal monomers to self-assemble, comprises: gradually evaporating the solvent until the solvent is removed at a first temperature, and performing the annealing treatment within a first period of time to allow the discotic liquid crystal monomers to self-assemble; the polymerizing the matrix monomers and the self-assembled discotic liquid crystal monomers to form the composite hole transport layer comprising the matrix and the discotic liquid crystal composition, comprises: at a second temperature, heating the matrix monomers and the self-assembled discotic liquid crystal monomers for a second period of time, thermally polymerizing the matrix monomer and the self-assembled discotic liquid crystal monomers to form the composite hole transport layer. A structural formula of the matrix monomers is

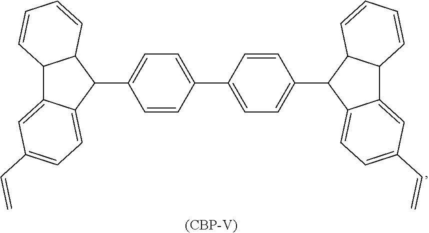 [SMILES: C=Cc1ccc2c(c1)C1C=CC=CC1C2c1ccc(-c2ccc(C3c4ccc(C=C)cc4C4C=CC=CC43)cc2)cc1 ; "(CBP-V)"]

a structural formula of the discotic liquid crystal monomers is

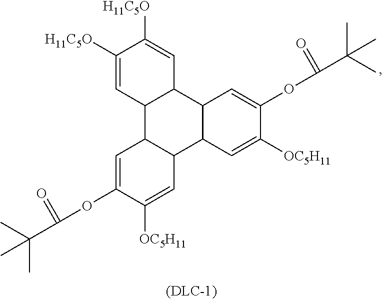

and a structural formula of the composite hole transport layer is

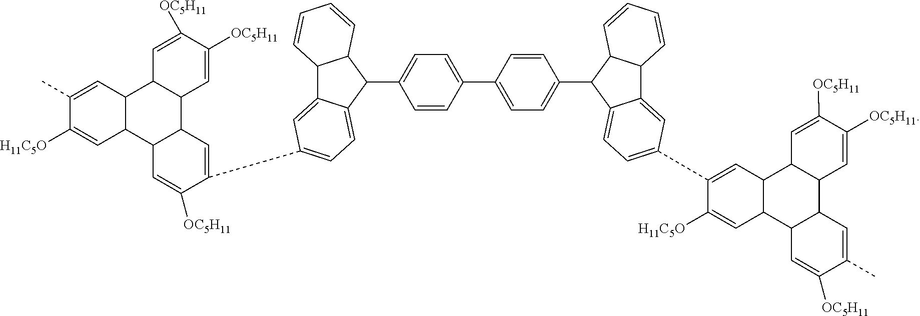

In some embodiments, the method further comprises: forming a first electrode layer; forming a hole injection layer on the first electrode layer; coating the mixed solution on a side of the hole injection layer away from the first electrode layer to form the composite hole transport layer; forming a light-emitting layer on a side of the composite hole transport layer away from the first electrode layer; forming an electron transport layer on a side of the light-emitting layer away from the first electrode layer; forming an electron injection layer on a side of the electron transport layer away from the first electrode layer; and forming a second electrode layer on a side of the electron injection layer away from the first electrode layer.

### BRIEF DESCRIPTION OF THE DRAWINGS

In order to describe the technical solutions in the embodiments of the present disclosure more clearly, the drawings needed to be used in the embodiments will be briefly introduced below. Obviously, the drawings in the following description are only some embodiments of the present disclosure. Those of ordinary skill in the art can also obtain other drawings based on these drawings without paying creative work.

FIG. 1 illustrates a schematic cross-sectional view of a partial structure of a light-emitting device according to an embodiment of the present disclosure;

FIG. 2 illustrates a general structural formula of a composite hole transport layer according to an embodiment of the present disclosure;

FIG. 3 illustrates a general structural formula of discotic liquid crystal monomers according to an embodiment of the present disclosure;

FIG. 4 illustrates a general structural formula of matrix monomers according to an embodiment of the present disclosure;

FIG. 5A illustrates a schematic cross-sectional view of a partial structure of a light-emitting device according to an embodiment of the present disclosure;

FIG. 5B illustrates a schematic cross-sectional view of a partial structure of another light-emitting device according to an embodiment of the present disclosure;

FIG. 6 illustrates a structural formula of a discotic liquid crystal monomer according to an embodiment of the present disclosure;

FIG. 7 illustrates a structural formula of a matrix monomer according to an embodiment of the present disclosure;

FIG. 8 illustrates a structural formula of the composite hole transport layer formed by the polymerization of the discotic liquid crystal monomers of FIG. 6 and the matrix monomers of FIG. 7;

FIG. 9 illustrates another structural formula of a discotic liquid crystal monomer according to an embodiment of the present disclosure;

FIG. 10 illustrates yet another structural formula of a discotic liquid crystal monomer according to an embodiment of the present disclosure;

FIG. 11 illustrates yet another structural formula of a discotic liquid crystal monomer according to an embodiment of the present disclosure;

FIG. 12 illustrates yet another structural formula of a discotic liquid crystal monomer according to an embodiment of the present disclosure;

FIG. 13 illustrates yet another structural formula of a discotic liquid crystal monomer according to an embodiment of the present disclosure;

FIG. 14 illustrates a block diagram of an array substrate according to an embodiment of the present disclosure;

FIG. 15 illustrates a schematic structural diagram of a display device according to an embodiment of the present disclosure;

FIG. 16 illustrates a flow chart of a method of preparing a light-emitting device according to an embodiment of the present disclosure;

FIG. 17 illustrates a polarizing microscope picture of a composite hole transport layer before annealing according to an embodiment of the present disclosure; and

FIG. 18 illustrates a polarizing microscope picture of a composite hole transport layer after annealing according to an embodiment of the present disclosure.

### DETAILED DESCRIPTION OF THE DISCLOSURE

The technical solutions in the embodiments of the present disclosure will be clearly described below with reference to the accompanying drawings. Obviously, the described embodiments are only some, but not all, of the embodiments of the present disclosure. Based on the embodiments of the present disclosure, all other embodiments obtained by those of ordinary skill in the art without undue experimentation fall within the scope of protection of this disclosure.

Quantum dot light-emitting diodes have become a competitive next-generation display technology due to their advantages such as wide color gamut, adjustable spectrum, and high color saturation. Most of the industry's development focus is on the material processing or structural design of the functional layers of red quantum dot light-emitting diode devices and green quantum dot light-emitting diode devices, whose external quantum efficiency (EQE) can be as high as 30%. In contrast, the development of external quantum efficiency of blue quantum dot light-emitting diode devices lags far behind that of red quantum dot light-emitting diode devices and green quantum dot light-emitting diode devices, and has become a key obstacle restricting the practical application of full-color display of quantum dot light-emitting diode devices. Severe non-radiative recombination resulting from unbalanced charge injection, which is mainly related to insufficient hole injection, is one of the main factors causing the above obstacles.

Quantum dot light-emitting diode devices comprise structures such as electron transport layers and hole transport layers. Generally, the hole transport layer is more mismatched to the energy levels of the quantum dot light-emitting diode device than the electron transport layer. In addition, the hole mobility of the hole transport layer (for example, about 10⁻⁶˜10⁻³ cm²V⁻¹s⁻¹) is significantly lower than the electron mobility of the electron transport layer (for example, about 10⁻³˜10⁻² cm²V⁻¹s⁻¹). How to improve the hole mobility of the hole transport layer and how to better match the energy level of the hole transport layer with the energy level of the quantum dot light-emitting diode device have a crucial impact on improving the performance of blue quantum dot light-emitting diode devices.

In order to overcome the problems existing in the prior art, the inventor of the present application proposed a composite hole transport layer. The composite hole transport layer has at least one of high hole mobility and an energy level matching the quantum dot light-emitting diode device, thereby significantly improving the performance of the blue quantum dot light-emitting diode device.

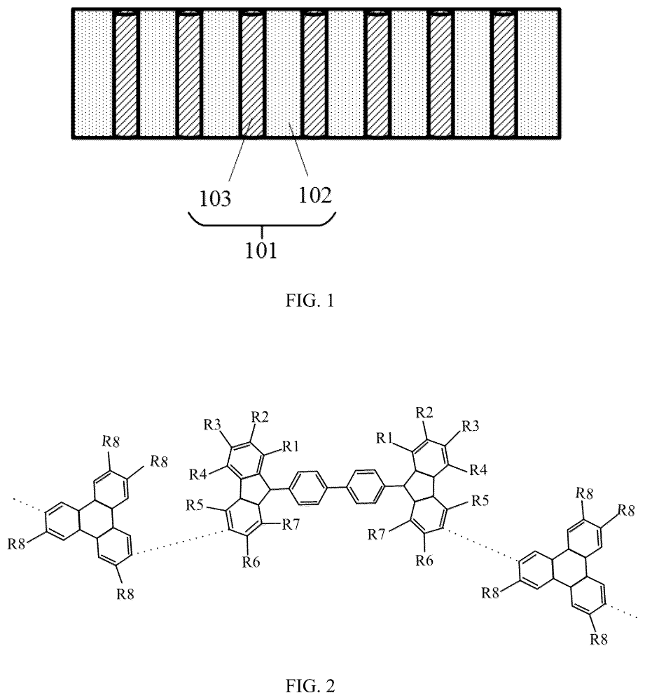

FIG. 1 illustrates a schematic cross-sectional view of a partial structure of a light-emitting device 100 according to an embodiment of the present disclosure. As illustrated in FIG. 1, the light-emitting device 100 comprises a composite hole transport layer 101. The composite hole transport layer 101 comprises a matrix 102 and a discotic liquid crystal component 103. The hole mobility of the discotic liquid crystal component 103 is greater than the hole mobility of the matrix 102.

By introducing the discotic liquid crystal component 103 with high hole mobility into the composite hole transport layer 101, the discotic liquid crystal component 103 can build a higher hole mobility molecular channel in the composite hole transport layer 101, so that the composite hole transport layer 101 has a higher hole mobility. As mentioned before, since the hole mobility in the quantum dot light-emitting diode device is usually lower than the electron mobility, by increasing the hole mobility of the composite hole transport layer 101, the balance of the hole mobility and electron mobility of the light-emitting device 100 can be promoted, which can improve the charge injection and transport capabilities, thereby significantly improving the overall efficiency and lifetime of the light-emitting device 100.

In some embodiments, the hole mobility of the composite hole transport layer 101 is 10⁻⁴˜10⁻³ cm²V⁻¹s⁻¹, for example, it may be 10⁻⁴ cm²V⁻¹s⁻¹, 10⁻³ cm²V⁻¹s⁻¹. It can be seen that compared with the hole mobility of the conventional hole transport layer of 10⁻⁶˜10⁻³ cm²V⁻¹s⁻¹, the introduction of the discotic liquid crystal component 103 with high hole mobility significantly improves the hole mobility of the composite hole transport layer 101, which can promote the balance of hole mobility and electron mobility of the light-emitting device 100, thereby significantly improving the overall efficiency and lifetime of the light-emitting device 100.

In some embodiments, the energy level of the highest occupied molecular orbital (HOMO) of the composite hole transport layer 101 is −6.0˜−5.3 eV, such as −6.0 eV, −5.8 eV, −5.6 eV, −5.4 eV, −5.3 eV. Therefore, the composite hole transport layer 103 not only has high hole mobility, but also has a deeper HOMO energy level, which can better match the energy level of the light-emitting device 100, thereby helping to further promote the overall improvement of the efficiency and lifetime of the light-emitting device 100. In some embodiments, the matrix 102 may have a deeper HOMO energy level, for example, the HOMO energy level may be −5.8˜−5.2 eV. The HOMO energy level of the matrix 102 in the composite hole transport layer 101 causes the composite hole transport layer 101 to exhibit a deeper HOMO energy level as a whole.

In some embodiments, the energy level of the lowest unoccupied molecular orbital (LUMO) of the composite hole transport layer 101 is −3.3˜−1.9 eV, such as −3.3 eV, −2.8 eV, −2.3 eV, −2.0 eV, −1.9 eV.

In some embodiments, the thickness of the composite hole transport layer 101 is 100˜150 nm, such as 100 nm, 125 nm, 150 nm. In some embodiments, the surface roughness of the composite hole transport layer 101 is 1˜5 nm, such as 1 nm, 3 nm, 5 nm.

As illustrated in FIG. 1, the discotic liquid crystal component 103 is arranged as columnar structures in an ordered manner in the composite hole transport layer 101. The height direction of the columnar structures is parallel to the thickness direction of the composite hole transport layer 101, and the matrix 102 is at least arranged among the plurality of columnar structures. In the process of preparing the composite hole transport layer 101, the discotic liquid crystal monomers are self-assembled to form columnar structures in an ordered manner with high hole mobility. The height direction of each columnar structure is parallel to the thickness direction of the composite hole transport layer 101 to form an ordered molecular orientation, so that a higher hole mobility molecular channel can be built in the composite hole transport layer 101 to promote carrier transport.

The matrix 102 and the discotic liquid crystal component 103 in the composite hole transport layer 101 need to be in an appropriate ratio, because the mass proportion of the discotic liquid crystal component 103 in the composite hole transport layer 101 has an important influence on the performance of the composite hole transport layer 101. Specifically, if the mass proportion of the discotic liquid crystal component 103 in the composite hole transport layer 101 is too low, it will result in poor hole mobility of the composite hole transport layer 101; if the mass proportion of the discotic liquid crystal component 103 in the composite hole transport layer 101 is too high, it will deteriorate the film uniformity of the composite hole transport layer 101, affect the potential barrier at the functional layer interface, thereby causing the carrier transport to become worse. Therefore, it is necessary to comprehensively consider the carrier mobility and film uniformity of the composite hole transport layer 101, and reasonably design the relative proportions of the discotic liquid crystal component 103 and the matrix 102, so that the composite hole transport layer 101 has high hole mobility and excellent film uniformity. In some embodiments, the mass proportion of the discotic liquid crystal component 103 in the composite hole transport layer 101 is 1%˜40%. For example, the mass proportion of the discotic liquid crystal component 103 in the composite hole transport layer 101 is 1%, 5%, 10%, 15%, 18%, 19%, 20%, 21%, 22%, 23%, 24%, 25%, 30%, 35%, 40%.

FIG. 2 illustrates a general structural formula of the composite hole transport layer 101, that is, the general structural formula of the composite hole transport layer 101 is:

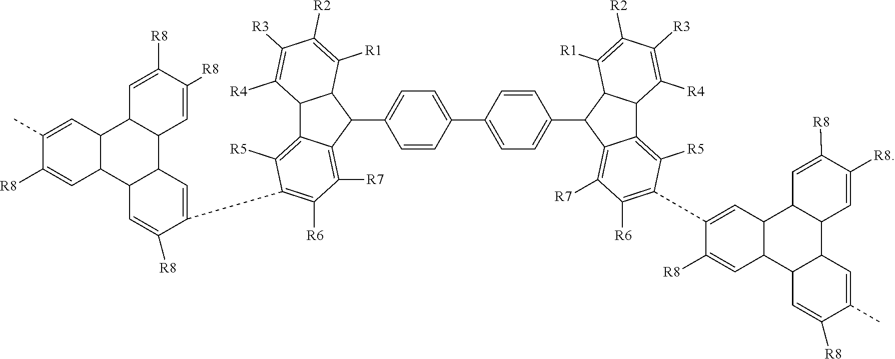

The discotic liquid crystal monomers and the matrix monomers are polymerized under specific conditions to form the composite hole transport layer 101. In the general structural formula of the composite hole transport layer 101, R8 is a branch chain, and the molecular structure connected to the branch chain R8 corresponds to the discotic core of the discotic liquid crystal monomer. R8 comprises, but is not limited to, an alkyl chain, an alkoxy chain, or an alkyl ester chain. In some examples, R8 may be any one of a butoxy, a pentyloxy, a hexyloxy, a butyl ester group, an amyl ester group, and a hexyl ester group. R8 at different positions of the general structural formula of the composite hole transport layer 101 may be the same as each other, or partially the same as each other, or different from each other. In an embodiment, R8 at different positions of the general structural formula of the composite hole transport layer 101 are the same as each other, which makes the general structural formula of the composite hole transport layer 101 have better symmetry, so that the discotic liquid crystal component 103 has better liquid crystallinity. R1˜R7 are branch chains, and the molecular structure connected to the branch chains R1˜R7 corresponds to the main chain of the matrix 102. Each of R1 to R7 can be a benzene ring, a double bond, a cyclohexane, or a hydrogen atom. It can be seen from the general structural formula of the composite hole transport layer 101 that the matrix monomer has a rigid core molecular structure, and the discotic liquid crystal monomer has a rigid discoid core and flexible side chains. After specific processing, the discotic liquid crystal monomers can self-assemble to form molecular stacks in an ordered manner with high hole mobility and are embedded in the matrix 102 with good film-forming properties, thereby forming the composite hole transport layer 101. The composite hole transport layer 101 having the above general structural formula combines the good film-forming property of the matrix 102 and the high mobility characteristic of the discotic liquid crystal component 103.

In order to ensure the mobility and polymerization performance of the discotic liquid crystal component 103, the substituent group R8 of the discotic liquid crystal monomer may choose a flexible alkyl chain with a moderate chain length to ensure the formation of liquid crystallinity of the molecule, that is, the discotic liquid crystal monomer has both a rigid core and flexible side chains. In some embodiments, R8 is a flexible alkyl chain having 4 to 6 carbon atoms, for example, R8 is a flexible alkyl chain having 4 carbon atoms, a flexible alkyl chain having 5 carbon atoms, or a flexible alkyl chain having 6 carbon atoms.

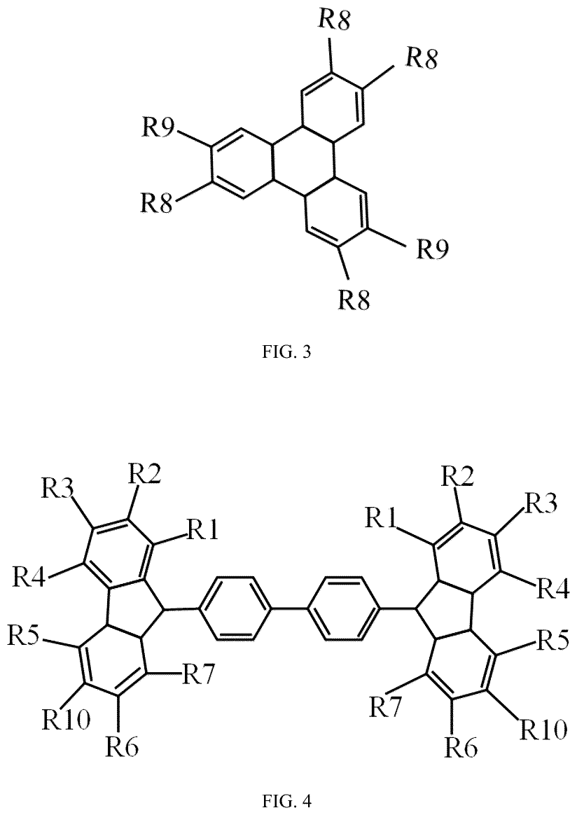

FIG. 3 illustrates a general structural formula of the discotic liquid crystal monomers, that is, the general structural formula is

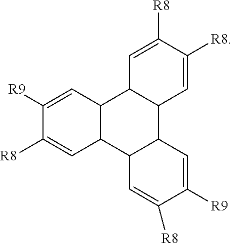

In the general structural formula of the discotic liquid crystal monomers, the substituent groups of the discotic liquid crystal monomer include two portions, namely the substituent functional group R8 and the polymerizable functional group R9. As mentioned above, R8 comprises, but is not limited to, an alkyl chain, an alkoxy chain, or an alkyl ester chain. In some examples, R8 may be any one of a butoxy, a pentyloxy, a hexyloxy, a butyl ester group, an amyl ester group, and a hexyl ester group. R8 at different positions of the general structural formula of the discotic liquid crystal monomers may be the same as each other, or partially the same as each other, or different from each other. In an embodiment, R8 at different positions of the general structural formula of the discotic liquid crystal monomer are the same as each other, which makes the general structural formula of the discotic liquid crystal monomers have better symmetry, thereby making the discotic liquid crystal monomer have better liquid crystallinity. The polymerizable functional group R9 may be a tert-butyl ethyl ester, an olefinic bond, an acrylate, a vinyl ether, a thiol, or an epoxy. As illustrated in FIG. 3, the two substituent groups R9 may be located at two distant substitution positions of the discotic liquid crystal monomer to facilitate cross-linking polymerization. However, this does not limit the positions of the two substituent groups R9 to be far apart. If necessary, the two substituent groups R9 may be designed at any two positions of the substitution positions of the discotic liquid crystal monomer. The discotic liquid crystal monomer has a rigid discotic core and flexible side chains. After certain processing, the discotic liquid crystal monomers can self-assemble into ordered molecular stacks with high hole mobility, for example, an ordered columnar structures, which makes the discotic liquid crystal component 103 have a higher hole mobility.

The discotic liquid crystal monomer may be a liquid crystal monomer or liquid crystal polymer material containing UV or thermal polymerizable functional groups, such as derivatives of discotic cores such as benzophenanthrene, hexabenzocorone, porphyrin.

In some embodiments, the hole mobility of the discotic liquid crystal component 103 is 10⁻³˜10⁻² cm²V⁻¹s⁻¹, such as 10⁻³ cm²V⁻¹s⁻¹, 10⁻² cm²V⁻¹s⁻¹. The hole mobility of the discotic liquid crystal component 103 is greater than the hole mobility of the matrix 102. By introducing the discotic liquid crystal component 103 with high hole mobility into the composite hole transport layer 101, the hole mobility of the composite hole transport layer 101 can be improved as a whole, and electron mobility of the light-emitting device 100 can be promoted, thereby helping to significantly improve the overall efficiency and lifetime of the light-emitting device 100.

In some embodiments, the HOMO energy level of the discotic liquid crystal component 103 is −6.5˜−5.5 eV, such as −6.5 eV, −6.3 eV, −6.0 eV, −5.8 eV, −5.5 eV. The HOMO energy level of the discotic liquid crystal component 103 matches the HOMO energy level of the matrix 102, so that the composite hole transport layer 101 has a deeper HOMO energy level (for example, −6.0˜−5.3 eV). As a result, the HOMO energy level of the composite hole transport layer 101 can better match the energy level of the light-emitting device 100, which helps to further promote the overall improvement of the efficiency and lifetime of the light-emitting device 100. In some embodiments, the LUMO energy level of the discotic liquid crystal component 103 is −3.0˜−1.8 eV, such as −3.0 eV, −2.5 eV, −2.0 eV, −1.8 eV. In some embodiments, the temperature range of the discotic liquid crystal component 103 may be −20° C. to 120° C.

In some embodiments, the matrix 102 in the composite hole transport layer 101 has no hole transport properties, and the high hole mobility of the composite hole transport layer 101 is achieved only depends on the discotic liquid crystal component 103. In some alternative embodiments, the matrix 102 in the composite hole transport layer 101 also has hole transport properties, the matrix 102 and the discotic liquid crystal component 103 can cause holes to migrate in an orderly manner in the composite hole transport layer 101 under the action of an electric field, thereby realizing the transport of holes. Therefore, the high hole mobility of the composite hole transport layer 101 depends on the cooperation of the matrix 102 and the discotic liquid crystal component 103, but the hole mobility of the matrix 102 is smaller than the hole mobility of the discotic liquid crystal component 103. FIG. 4 illustrates a general structural formula of the matrix monomers, that is, the general structural formula is

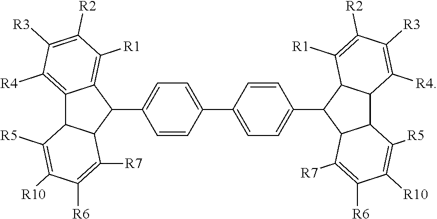

Matrix monomers comprise but are not limited to TFB, poly-TFD, CBP-V, etc. In the general structural formula of the matrix monomer, the substituent groups of the matrix monomer comprise two portions, namely the substituent functional group R1˜R7 and the polymerizable functional group R10. As mentioned before, each of R1˜R7 may be an olefin, an acrylate, a vinyl ether, a thiol, an epoxy, etc. The polymerizable functional group R10 may be a rigid substituent, such as an olefin, an acrylate, a vinyl ether, a thiol, or an epoxy. The matrix monomer has a molecular structure with a rigid core, so that the matrix monomer has good film-forming properties.

In some embodiments, the hole mobility of the matrix 102 is 10⁻⁶˜10⁻³ cm²V⁻¹s⁻¹, such as 10⁻⁶ cm²V⁻¹s⁻¹, 10⁻⁵ cm²V⁻¹s⁻¹, 10⁻⁴ cm²V⁻¹s⁻¹, 10⁻³ cm²V⁻¹s⁻¹. The HOMO energy level of the matrix 102 is −5.8˜−5.2 eV, such as −5.8 eV, −5.6 eV, −5.4 eV, −5.2 eV. The LUMO energy level of the matrix 102 is −3.6˜−2.0 eV, such as −3.6 eV, −3.0 eV, −2.5 eV, −2.0 eV. The matrix 102 has a deeper HOMO energy level, so that the composite hole transport layer 101 comprising the matrix 102 not only has a high hole mobility, but also has a HOMO energy level that better match with the energy level of the light-emitting device 100, thereby helping to further promote the overall improvement of the efficiency and lifetime of the light-emitting device 100.

In some embodiments, each of R1 to R7 of the matrix monomer is a hydrogen atom, the polymerizable functional group R10 of the matrix monomer is an olefinic bond, and the substituent group R8 of the discotic liquid crystal monomer is an alkoxy chain, and the polymerizable functional group R9 of the discotic liquid crystal monomer is tert-butyl ethyl ester.

The preparation of the composite hole transport layer 101 may be achieved by using processes such as ultraviolet polymerization or thermal polymerization. The specific preparation method will be clearly described hereinafter. When the composite hole transport layer 101 is realized by a UV polymerization process, at least one of the polymerizable functional group R9 of the discotic liquid crystal monomer and the polymerizable functional group R10 of the matrix monomer is a UV polymerizable functional group, and the UV polymerization functional group comprises at least one bifunctional monomer. During UV polymerization, the monomer with UV polymerization functional group polymerizes and cross-links in the entire material system, thereby forming the composite hole transport layer 101. When the composite hole transport layer 101 is realized by a thermal polymerization process, at least one of the polymerizable functional group R9 of the discotic liquid crystal monomer and the polymerizable functional group R10 of the matrix monomer is a thermally polymerizable functional group, and the thermally polymerizable functional group comprises at least one bifunctional monomer. During thermal polymerization, the monomer with the thermally polymerizable functional group polymerizes and cross-links in the entire material system, thereby forming the composite hole transport layer 101.

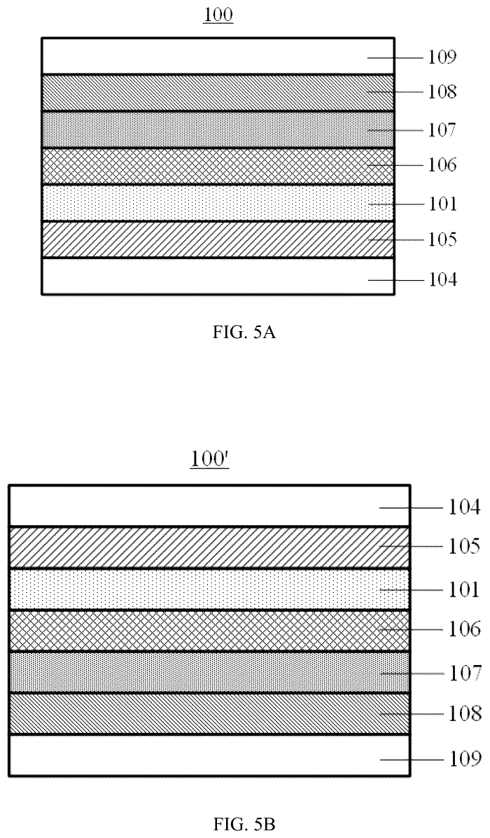

FIG. 5A illustrates a schematic cross-sectional view of a partial structure of the light-emitting device 100. As illustrated in FIG. 5A, the light-emitting device 100 may further comprise: a first electrode layer 104; a hole injection layer 105 on the first electrode layer 104, and the composite hole transport layer 101 on the side of the hole injection layer 105 away from the first electrode layer 104, the composite hole transport layer 101 may be the composite hole transport layer described in any of the previous embodiments; a light-emitting layer 106 on the side of the composite hole transport layer 101 away from the first electrode layer 104; an electron transport layer 107 on the side of the light-emitting layer 106 away from the first electrode layer 104; an electron injection layer 108 located on the side of the electron transport layer 107 away from the first electrode layer 104; and a second electrode layer 109 on the side of the electron injection layer 108 away from the first electrode layer 104. The light-emitting device 100 illustrated in FIG. 5A may be called a positive structure.

FIG. 5B illustrates a schematic cross-sectional view of a partial structure of another light-emitting device 100′. As illustrated in FIG. 5B, the light-emitting device 100′ comprises: a second electrode layer 109; an electron injection layer 108 on the second electrode layer 109; an electron transport layer 107 on the side of the electron injection layer 108 away from the second electrode layer 109; a light-emitting layer 106 on the side of the electron transport layer 107 away from the second electrode layer 109; a composite hole transport layer 101 on the side of the light-emitting layer 106 away from the second electrode layer 109, the composite hole transport layer 101 may be the composite hole transport layer described in any of the previous embodiments; a hole injection layer 105 on the side of the composite hole transport layer 101 away from the second electrode layer 109; and the first electrode layer 104 on the side of the hole injection layer 105 away from the second electrode layer 109. The light-emitting device 100′ illustrated in FIG. 5B may be called an inverted structure.

The light-emitting layer 106 can be made of various appropriate materials, such as InP, CdSe/ZnS core-shell structure, perovskite. The embodiments of the present disclosure do not specifically limit the material of the light-emitting layer 106. In some embodiments, the light-emitting layer 106 comprises quantum dots configured to emit blue light, and the emission peak of the blue quantum dot light-emitting layer may be 455˜465 nm, the wavelength range corresponds to deep blue light, the full width at half maximum can be 15˜30 nm, and the value of the color coordinate CIE can be 0.035˜0.050. The material of the electron transport layer 107 may be an inorganic oxide material with high electron mobility, such as ZnO. The material of the electron injection layer 108 may be polyvinylpyrrolidone (PVP). The material of the hole injection layer 105 may be a material with high injection capability, such as poly(3,4-ethylenedioxythiophene): polystyrenesulfonate (PEDOT:PSS). The first electrode layer 104 may be an anode, and its material may be, for example, indium tin oxide (ITO). The second electrode layer 109 may be a cathode, and its material may be, for example, Al.

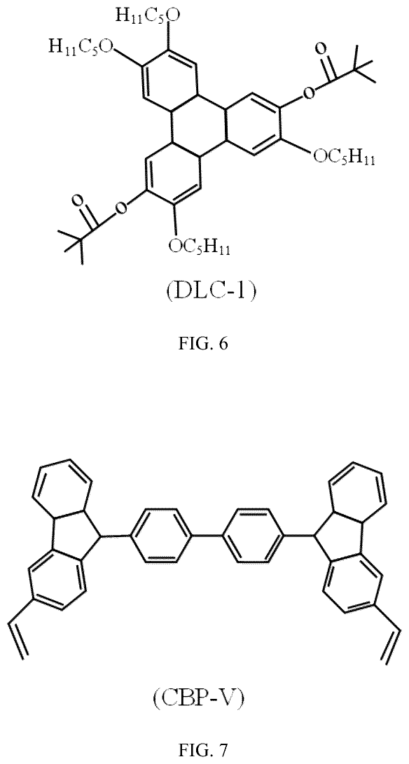

In an embodiment, the material of the first electrode layer 104 in the light-emitting device 100 is ITO, the material of the hole injection layer 105 is PEDOT:PSS, the material of the electron transport layer 107 is ZnO, and the material of the electron injection layer 108 is PVP, the material of the second electrode 109 is Al. The discotic liquid crystal monomer used to form the discotic liquid crystal component 103 in the composite hole transport layer 101 is DLC-1, FIG. 6 illustrates the structural formula of discotic liquid crystal monomer DLC-1, namely

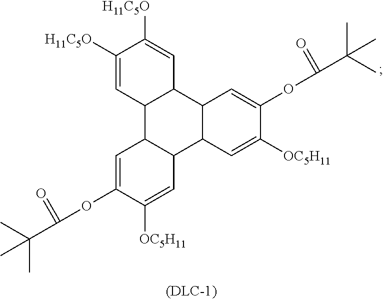

the matrix monomer used to form the matrix 102 in the composite hole transport layer 101 is CBP-V, FIG. 7 illustrates the structural formula of the matrix monomer CBP-V, namely

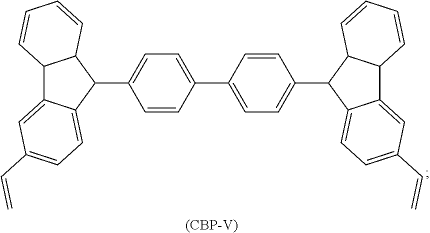 [SMILES: C=Cc1ccc2c(c1)C1C=CC=CC1C2c1ccc(-c2ccc(C3c4ccc(C=C)cc4C4C=CC=CC43)cc2)cc1 ; "(CBP-V)"]

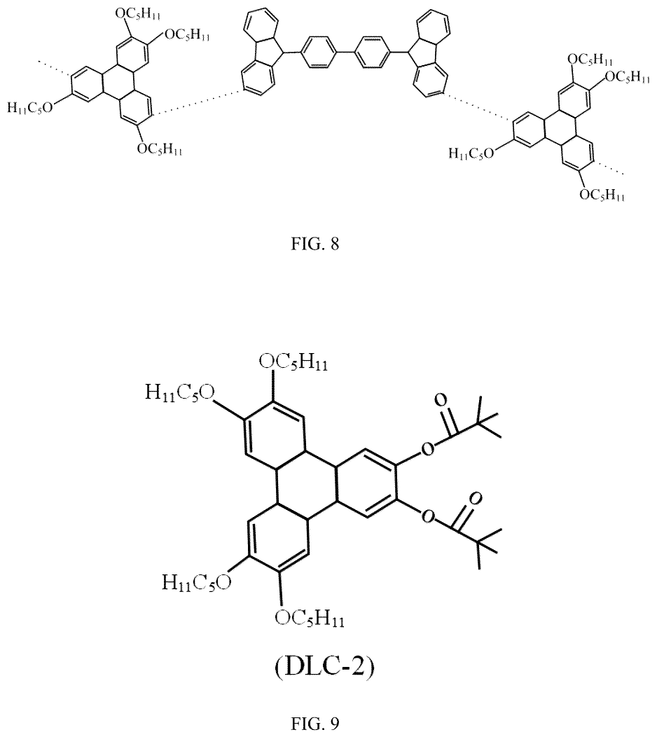

FIG. 8 illustrates the structural formula of the composite hole transport layer 101 composed of the discotic liquid crystal monomer DLC-1 and the matrix monomer CBP-V, namely

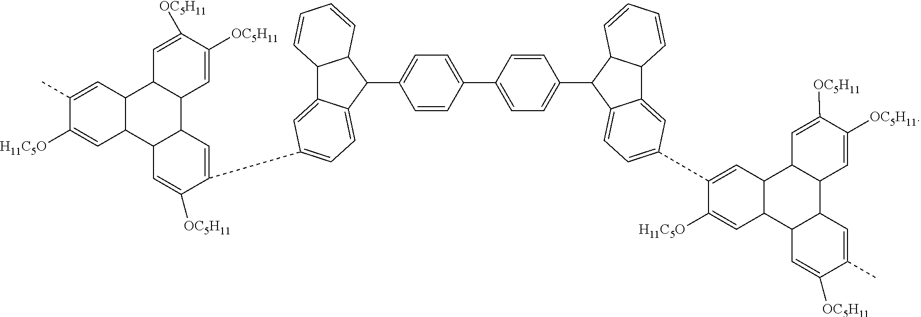

In this embodiment, the mass proportion of the discotic liquid crystal component 103 in the composite hole transport layer 101 is 20%, and the mass proportion of the matrix 102 in the composite hole transport layer 101 is 80%. That is, the mass ratio of the discotic liquid crystal component 103 to the matrix 102 is 2:8.

In this embodiment, the mass proportion of the discotic liquid crystal component 103 in the composite hole transport layer 101 is 20%, and the composite hole transport layer 101 exhibits excellent performance. When the mass proportion of the discotic liquid crystal component 103 in the composite hole transport layer 101 is less than 20%, the content of liquid crystal molecules is relatively small, and the carrier mobility of the composite hole transport layer 101 will be affected; when the mass proportion of the discotic liquid crystal component 103 in the composite hole transport layer 101 is greater than 20%, the film uniformity of the composite hole transport layer 101 becomes worse, affecting the potential barrier at the functional layer interface, thereby causing the carrier transport to become worse. Therefore, when the mass proportion of the discotic liquid crystal component 103 in the composite hole transport layer 101 is 20%, the composite hole transport layer 101 can have both high carrier mobility and good film uniformity. By increasing the hole mobility of the composite hole transport layer 101, the balance of hole mobility and electron mobility of the light-emitting device 100 can be promoted, and the charge injection and transport capabilities can be improved. The light-emitting device 100 in this embodiment has higher current efficiency, higher external quantum efficiency, and longer working lifetime. The light-emitting device 100 in this embodiment corresponds to the device in Example 3 in Table 1. For specific values of its current efficiency, quantum efficiency, and working lifetime, please refer to the values listed in Embodiment 3 in Table 1.

It should be noted that, in addition to blue quantum dots, the light-emitting layer 106 of the light-emitting device 100 in the embodiment of the present disclosure may also be red quantum dots or green quantum dots.

In some embodiments, the light-emitting layer 106 comprises quantum dots configured to emit red light, the mass proportion of the discotic liquid crystal component 103 in the composite hole transport layer 101 is 25%˜30%, such as 25%, 27.5%, 30%, and the emission peak wavelength of red light is 620˜640 nm, such as 620 nm, 630 nm, 640 nm. Under the premise of ensuring the hole mobility, by making the mass proportion of the discotic liquid crystal component 103 in the composite hole transport layer 101 be 25%˜30%, the composite hole transport layer 101 can be made to better match the energy level of the red quantum dot light-emitting layer 106, thereby further promoting carrier transport.

In some alternative embodiments, the light-emitting layer 106 comprises quantum dots configured to emit green light, and the mass proportion of the discotic liquid crystal component 103 in the composite hole transport layer 101 is 20% to 25%, such as 20%, 22.5%, 25%, and the emission peak wavelength of green light is 525˜535 nm, such as 525 nm, 530 nm, 535 nm. Under the premise of ensuring the hole mobility, by making the mass proportion of the discotic liquid crystal component 103 in the composite hole transport layer 101 be 20%˜25%, the composite hole transport layer 101 can be made to better match the energy level of the green quantum dot light-emitting layer 106, thereby further promoting carrier transport.

The preparation methods and corresponding electro-optical parameters of different light-emitting devices in several examples are given below.

### Embodiment 1

In Embodiment 1, the materials of individual film layer of the light-emitting device are: the material of the first electrode layer 104 is ITO, the material of the hole injection layer 105 is PEDOT:PSS, the light-emitting layer 106 is blue quantum dots with an emission peak of 455˜465 nm, the material of the electron transport layer 107 is ZnO, the material of the electron injection layer 108 is PVP, and the material of the second electrode layer 109 is Al. The composite hole transport layer 101 is formed by cross-linking polymerization of the discotic liquid crystal monomer DLC-1 illustrated in FIG. 6 and the matrix monomer CBP-V illustrated in FIG. 7, wherein the mass proportion of the discotic liquid crystal component 103 in the composite hole transport layer 101 is 0%, that is, the mass ratio of the matrix 102 to the discotic liquid crystal component 103 is equal to 1:0. The preparation process of the composite hole transport layer 101 is roughly as follows: dissolving the matrix monomers CBP-V and the discotic liquid crystal monomers DLC-1 in toluene solvent at a mass ratio of 1:0 to form a mixed solution, then coating the mixed solution on the surface of the hole injection layer 105 away from the first electrode layer 104. At a temperature of 120° C., the solvent in the mixed solution was removed, and the annealing process was performed for about 0.5 hours, and the self-assembly of the discotic liquid crystal monomer DLC-1 was completed. Then, heating at 240° C. for about 1.5 hours, the discotic liquid crystal monomers DLC-1 and the matrix monomers CBP-V are thermally polymerized and cross-linked to form a uniform polymer film, thereby forming the composite hole transport layer 101. Then, film layers such as the light-emitting layer 106, the electron transport layer 107, the electron injection layer 108, and the second electrode layer 109 are sequentially formed on the composite hole transport layer 101, thereby preparing a light-emitting device. An optoelectronic testing system was used to characterize the driving voltage, current efficiency, external quantum efficiency, and working lifetime of the light-emitting device of Embodiment 1. The test results are illustrated in Embodiment 1 of Table 1. Embodiment 1 can be used as a comparison example.

### Embodiment 2

In Embodiment 2, the materials of the first electrode layer 104, the hole injection layer 105, the light-emitting layer 106, the electron transport layer 107, the electron injection layer 108, the second electrode layer 109, and the composite hole transport layer 101 are the same as that of Embodiment 1. The difference is that the mass proportion of the discotic liquid crystal component 103 in the composite hole transport layer 101 in Embodiment 2 is 10%, that is, the mass ratio of the matrix 102 to the discotic liquid crystal component 103 is equal to 9:1. The preparation process of the composite hole transport layer 101 is roughly as follows: first, dissolving the matrix monomers CBP-V and the discotic liquid crystal monomers DLC-1 in a toluene solvent at a mass ratio of 9:1 to form a mixed solution. Then, removing solvent, annealing, polymerization and other processes are performed under the same conditions as Embodiment 1 to form the composite hole transport layer 101. Then, sequentially forming film layers such as the light-emitting layer 106, the electron transport layer 107, the electron injection layer 108, and the second electrode layer 109 on the composite hole transport layer 101, thereby preparing a light-emitting device. An optoelectronic testing system was used to characterize the driving voltage, current efficiency, external quantum efficiency, and working lifetime of the light-emitting device of Embodiment 2. The test results are illustrated in Embodiment 2 of Table 1.

### Embodiment 3

In Embodiment 3, the materials of the first electrode layer 104, the hole injection layer 105, the light-emitting layer 106, the electron transport layer 107, the electron injection layer 108, the second electrode layer 109, and the composite hole transport layer 101 of the light-emitting device are the same as Embodiment 1. The difference is that the mass proportion of the discotic liquid crystal component 103 in the composite hole transport layer 101 in Embodiment 3 is 20%, that is, the mass ratio of the matrix 102 to the discotic liquid crystal component 103 is equal to 8:2. The preparation process of the composite hole transport layer 101 is roughly as follows: first, dissolving the matrix monomers CBP-V and the discotic liquid crystal monomers DLC-1 in a toluene solvent at a mass ratio of 8:2 to prepare a mixed solution. Then, removing solvent, annealing, polymerization and other processes are performed under the same conditions as Embodiment 1 to form the composite hole transport layer 101. Then, sequentially forming film layers such as the light-emitting layer 106, the electron transport layer 107, the electron injection layer 108, and the second electrode layer 109 on the composite hole transport layer 101, thereby preparing a light-emitting device. An optoelectronic testing system was used to characterize the driving voltage, current efficiency, external quantum efficiency, and working lifetime of the light-emitting device of Embodiment 3. The test results are illustrated in Embodiment of Table 1.

### Embodiment 4

In this Embodiment 4, the materials of the first electrode layer 104, the hole injection layer 105, the light-emitting layer 106, the electron transport layer 107, the electron injection layer 108, the second electrode layer 109, and the composite hole transport layer 101 of the light-emitting device are same as Embodiment 1. The difference is that the mass ratio of the discotic liquid crystal component 103 in the composite hole transport layer 101 in Embodiment 4 is 30%, that is, the mass ratio of the matrix 102 to the discotic liquid crystal component 103 is equal to 7:3. The preparation process of the composite hole transport layer 101 is roughly as follows: first, dissolving the matrix monomers CBP-V and the discotic liquid crystal monomers DLC-1 in a toluene solvent at a mass ratio of 7:3 to prepare a mixed solution. Then, removing solvent, annealing, polymerization and other processes are performed under the same conditions as Embodiment 1 to form the composite hole transport layer 101. Then, sequentially forming film layers such as the light-emitting layer 106, the electron transport layer 107, the electron injection layer 108, and the second electrode layer 109 on the composite hole transport layer 101, thereby preparing a light-emitting device. An optoelectronic testing system was used to characterize the driving voltage, current efficiency, external quantum efficiency, and working lifetime of the light-emitting device of Embodiment 4. The test results are illustrated in Embodiment 4 of Table 1.

### Embodiment 5

In Embodiment 5, the materials of the first electrode layer 104, the hole injection layer 105, the light-emitting layer 106, the electron transport layer 107, the electron injection layer 108, the second electrode layer 109, and the composite hole transport layer 101 of the light-emitting device are as same as Embodiment 1. The difference is that the mass ratio of the discotic liquid crystal component 103 in the composite hole transport layer 101 in Embodiment 5 is 40%, that is, the mass ratio of the matrix 102 to the discotic liquid crystal component 103 is equal to 6:4. The preparation process of the composite hole transport layer 101 is roughly as follows: first, dissolving the matrix monomers CBP-V and the discotic liquid crystal monomers DLC-1 in a toluene solvent at a mass ratio of 6:4 to prepare a mixed solution. Then, removing solvent, annealing, polymerization and other processes are performed under the same conditions as Embodiment 1 to form the composite hole transport layer 101. Then, sequentially forming film layers such as the light-emitting layer 106, the electron transport layer 107, the electron injection layer 108, and the second electrode layer 109 on the composite hole transport layer 101, thereby preparing a light-emitting device. An optoelectronic testing system was used to characterize the driving voltage, current efficiency, external quantum efficiency, and working lifetime of the light-emitting device of Embodiment 5. The test results are illustrated in Embodiment of Table 1.

### Embodiment 6

In Embodiment 6, the materials of the first electrode layer 104, the hole injection layer 105, the light-emitting layer 106, the electron transport layer 107, the electron injection layer 108, and the second electrode layer 109 of the light-emitting device are the same as in Embodiment 1. The difference is that the composite hole transport layer 101 in Embodiment 6 is formed by cross-linking polymerization of the discotic liquid crystal monomer DLC-2 illustrated in FIG. 9 and the matrix monomer CBP-V illustrated in FIG. 7, the mass proportion of the discotic liquid crystal component 103 in the composite hole transport layer 101 is 20%, that is, the mass ratio of the matrix 102 to the discotic liquid crystal component 103 is equal to 8:2. The preparation process of the composite hole transport layer 101 is roughly as follows: first, dissolving the matrix monomers CBP-V and the discotic liquid crystal monomers DLC-2 in a toluene solvent at a mass ratio of 8:2 to prepare a mixed solution. Then, removing solvent, annealing, polymerization and other processes are performed under the same conditions as Embodiment 1 to form the composite hole transport layer 101. Then, sequentially forming film layers such as the light-emitting layer 106, the electron transport layer 107, the electron injection layer 108, and the second electrode layer 109 on the composite hole transport layer 101, thereby preparing a light-emitting device. An optoelectronic testing system was used to characterize the driving voltage, current efficiency, external quantum efficiency, and working lifetime of the light-emitting device of Embodiment 6. The test results are illustrated in Embodiment 6 of Table 1.

### Embodiment 7

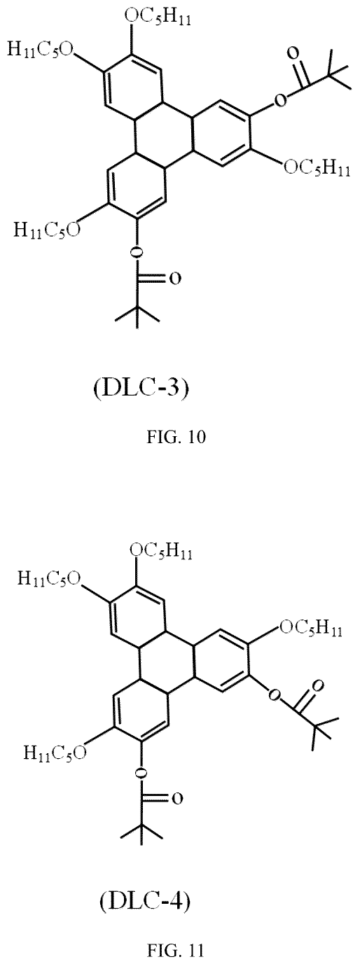

In Embodiment 7, the materials of the first electrode layer 104, the hole injection layer 105, the light-emitting layer 106, the electron transport layer 107, the electron injection layer 108, and the second electrode layer 109 of the light-emitting device are the same as in Embodiment 1. The difference is that the composite hole transport layer 101 in Embodiment 7 is formed by cross-linking polymerization of the discotic liquid crystal monomer DLC-3 illustrated in FIG. 10 and the matrix monomer CBP-V illustrated in FIG. 7, the mass proportion of the discotic liquid crystal component 103 in the composite hole transport layer 101 is 20%, that is, the mass ratio of the matrix 102 to the discotic liquid crystal component 103 is equal to 8:2. The preparation process of the composite hole transport layer 101 is roughly as follows: first, dissolving the matrix monomers CBP-V and the discotic liquid crystal monomers DLC-3 in a toluene solvent at a mass ratio of 8:2 to prepare a mixed solution. Then, removing solvent, annealing, polymerization and other processes are performed under the same conditions as Embodiment 1 to form the composite hole transport layer 101. Then, sequentially forming film layers such as the light-emitting layer 106, the electron transport layer 107, the electron injection layer 108, and the second electrode layer 109 on the composite hole transport layer 101, thereby preparing a light-emitting device. An optoelectronic testing system was used to characterize the driving voltage, current efficiency, external quantum efficiency, and working lifetime of the light-emitting device in Embodiment 7. The test results are illustrated in Embodiment 7 in Table 1.

### Embodiment 8

In Embodiment 8, the materials of the first electrode layer 104, the hole injection layer 105, the light-emitting layer 106, the electron transport layer 107, the electron injection layer 108, and the second electrode layer 109 of the light-emitting device are the same as in Embodiment 1. The difference is that the composite hole transport layer 101 in Embodiment 8 is formed by cross-linking polymerization of the discotic liquid crystal monomer DLC-4 illustrated in FIG. 11 and the matrix monomer CBP-V illustrated in FIG. 7, the mass proportion of the discotic liquid crystal component 103 in the composite hole transport layer 101 is 20%, that is, the mass ratio of the matrix 102 to the discotic liquid crystal component 103 is equal to 8:2. The preparation process of the composite hole transport layer 101 is roughly as follows: first, dissolving the matrix monomers CBP-V and the discotic liquid crystal monomers DLC-4 in a toluene solvent at a mass ratio of 8:2 to prepare a mixed solution. Then, removing solvent, annealing, polymerization and other processes are performed under the same conditions as Embodiment 1 to form the composite hole transport layer 101. Then, sequentially forming film layers such as the light-emitting layer 106, the electron transport layer 107, the electron injection layer 108, and the second electrode layer 109 on the composite hole transport layer 101, thereby preparing a light-emitting device. An optoelectronic testing system was used to characterize the driving voltage, current efficiency, external quantum efficiency, and working lifetime of the light-emitting device in Embodiment 8. The test results are illustrated in Embodiment 8 in Table 1.

### Embodiment 9

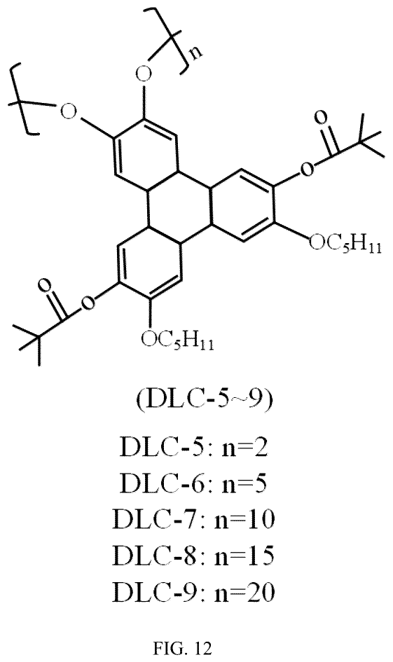

In Embodiment 9, the materials of the first electrode layer 104, the hole injection layer 105, the light-emitting layer 106, the electron transport layer 107, the electron injection layer 108, and the second electrode layer 109 of the light-emitting device are the same as in Embodiment 1. The difference is that the composite hole transport layer 101 in Embodiment 9 is formed by cross-linking polymerization of the discotic liquid crystal monomer DLC-5 illustrated in FIG. 12 and the matrix monomer CBP-V illustrated in FIG. 7. In FIG. 12, when the discotic liquid crystal monomer is DLC-5, n in the molecular structural formula is equal to 2. The mass proportion of the discotic liquid crystal component 103 in the composite hole transport layer 101 is 20%, that is, the mass ratio of the matrix 102 to the discotic liquid crystal component 103 is equal to 8:2. The preparation process of the composite hole transport layer 101 is roughly as follows: first, dissolving the matrix monomers CBP-V and the discotic liquid crystal monomers DLC-5 in a toluene solvent at a mass ratio of 8:2 to prepare a mixed solution. Then, removing solvent, annealing, polymerization and other processes are performed under the same conditions as Embodiment 1 to form the composite hole transport layer 101. Then, sequentially forming film layers such as the light-emitting layer 106, the electron transport layer 107, the electron injection layer 108, and the second electrode layer 109 on the composite hole transport layer 101, thereby preparing a light-emitting device. An optoelectronic testing system was used to characterize the driving voltage, current efficiency, external quantum efficiency, and working lifetime of the light-emitting device in Embodiment 9. The test results are illustrated in Embodiment 9 in Table 1.

### Embodiment 10

In Embodiment 10, the materials of the first electrode layer 104, the hole injection layer 105, the light-emitting layer 106, the electron transport layer 107, the electron injection layer 108, and the second electrode layer 109 of the light-emitting device are the same as in Embodiment 1. The difference is that the composite hole transport layer 101 in Embodiment 10 is formed by cross-linking polymerization of the discotic liquid crystal monomer DLC-6 illustrated in FIG. 12 and the matrix monomer CBP-V illustrated in FIG. 7. In FIG. 12, when the discotic liquid crystal monomer is DLC-6, n in the molecular structural formula is equal to 5. The mass proportion of the discotic liquid crystal component 103 in the composite hole transport layer 101 is 20%, that is, the mass ratio of the matrix 102 to the discotic liquid crystal component 103 is equal to 8:2. The preparation process of the composite hole transport layer 101 is roughly as follows: first, dissolving the matrix monomers CBP-V and the discotic liquid crystal monomers DLC-6 in a toluene solvent at a mass ratio of 8:2 to prepare a mixed solution. Then, removing solvent, annealing, polymerization and other processes are performed under the same conditions as Embodiment 1 to form the composite hole transport layer 101. Then, sequentially forming film layers such as the light-emitting layer 106, the electron transport layer 107, the electron injection layer 108, and the second electrode layer 109 on the composite hole transport layer 101, thereby preparing a light-emitting device. An optoelectronic testing system was used to characterize the driving voltage, current efficiency, external quantum efficiency, and working lifetime of the light-emitting device of Embodiment 10. The test results are illustrated in Embodiment 10 of Table 1.

### Embodiment 11

In Embodiment 11, the materials of the first electrode layer 104, the hole injection layer 105, the light-emitting layer 106, the electron transport layer 107, the electron injection layer 108, and the second electrode layer 109 of the light-emitting device are the same as in Embodiment 1. The difference is that the composite hole transport layer 101 in Embodiment 11 is formed by cross-linking polymerization of the discotic liquid crystal monomer DLC-7 illustrated in FIG. 12 and the matrix monomer CBP-V illustrated in FIG. 7. In FIG. 12, when the discotic liquid crystal monomer is DLC-7, n in the molecular structural formula is equal to 10. The mass proportion of the discotic liquid crystal component 103 in the composite hole transport layer 101 is 20%, that is, the mass ratio of the matrix 102 to the discotic liquid crystal component 103 is equal to 8:2. The preparation process of the composite hole transport layer 101 is roughly as follows: first, dissolving the matrix monomers CBP-V and the discotic liquid crystal monomers DLC-7 in a toluene solvent at a mass ratio of 8:2 to prepare a mixed solution. Then, removing solvent, annealing, polymerization and other processes are performed under the same conditions as Embodiment 1 to form the composite hole transport layer 101. Then, sequentially forming film layers such as the light-emitting layer 106, the electron transport layer 107, the electron injection layer 108, and the second electrode layer 109 on the composite hole transport layer 101, thereby preparing a light-emitting device. An optoelectronic testing system was used to characterize the driving voltage, current efficiency, external quantum efficiency, and working lifetime of the light-emitting device of Embodiment 11. The test results are illustrated in Embodiment 11 of Table 1.

### Embodiment 12

In Embodiment 12, the materials of the first electrode layer 104, the hole injection layer 105, the light-emitting layer 106, the electron transport layer 107, the electron injection layer 108, and the second electrode layer 109 of the light-emitting device are the same as in Embodiment 1. The difference is that the composite hole transport layer 101 in Embodiment 12 is formed by cross-linking polymerization of the discotic liquid crystal monomer DLC-8 illustrated in FIG. 12 and the matrix monomer CBP-V illustrated in FIG. 7. In FIG. 12, when the discotic liquid crystal monomer is DLC-8, n in the molecular structural formula is equal to 15. The mass proportion of the discotic liquid crystal component 103 in the composite hole transport layer 101 is 20%, that is, the mass ratio of the matrix 102 to the discotic liquid crystal component 103 is equal to 8:2. The preparation process of the composite hole transport layer 101 is roughly as follows: first, dissolving the matrix monomers CBP-V and the discotic liquid crystal monomers DLC-8 in a toluene solvent at a mass ratio of 8:2 to prepare a mixed solution. Then, removing solvent, annealing, polymerization and other processes are performed under the same conditions as Embodiment 1 to form the composite hole transport layer 101. Then, sequentially forming film layers such as the light-emitting layer 106, the electron transport layer 107, the electron injection layer 108, and the second electrode layer 109 on the composite hole transport layer 101, thereby preparing a light-emitting device. An optoelectronic testing system was used to characterize the driving voltage, current efficiency, external quantum efficiency, and working lifetime of the light-emitting device of Embodiment 12. The test results are illustrated in Embodiment 12 of Table 1.

### Embodiment 13

In Embodiment 13, the materials of the first electrode layer 104, the hole injection layer 105, the light-emitting layer 106, the electron transport layer 107, the electron injection layer 108, and the second electrode layer 109 of the light-emitting device are the same as in Embodiment 1. The difference is that the composite hole transport layer 101 in Embodiment 13 is formed by cross-linking polymerization of the discotic liquid crystal monomer DLC-9 illustrated in FIG. 12 and the matrix monomer CBP-V illustrated in FIG. 7. In FIG. 12, when the discotic liquid crystal monomer is DLC-9, n in the molecular structural formula is equal to 20. The mass proportion of the discotic liquid crystal component 103 in the composite hole transport layer 101 is 20%, that is, the mass ratio of the matrix 102 to the discotic liquid crystal component 103 is equal to 8:2. The preparation process of the composite hole transport layer 101 is roughly as follows: first, dissolving the matrix monomers CBP-V and the discotic liquid crystal monomers DLC-9 in a toluene solvent at a mass ratio of 8:2 to prepare a mixed solution. Then, removing solvent, annealing, polymerization and other processes are performed under the same conditions as Embodiment 1 to form the composite hole transport layer 101. Then, sequentially forming film layers such as the light-emitting layer 106, the electron transport layer 107, the electron injection layer 108, and the second electrode layer 109 on the composite hole transport layer 101, thereby preparing a light-emitting device. An optoelectronic testing system was used to characterize the driving voltage, current efficiency, external quantum efficiency, and working lifetime of the light-emitting device of Embodiment 13. The test results are illustrated in Embodiment 13 of Table 1.

### Embodiment 14

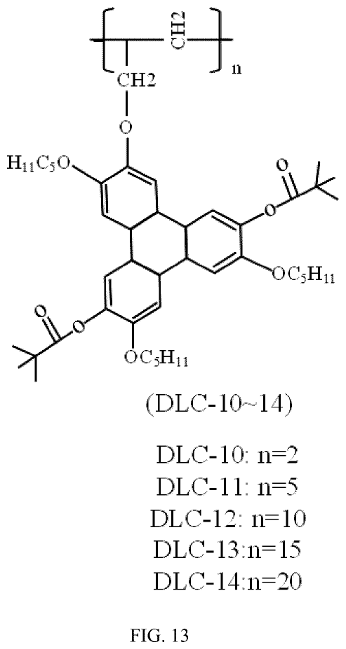

In Embodiment 14, the materials of the first electrode layer 104, the hole injection layer 105, the light-emitting layer 106, the electron transport layer 107, the electron injection layer 108, and the second electrode layer 109 of the light-emitting device are the same as in Embodiment 1. The difference is that the composite hole transport layer 101 in Embodiment 14 is formed by cross-linking polymerization of the discotic liquid crystal monomer DLC-10 illustrated in FIG. 13 and the matrix monomer CBP-V illustrated in FIG. 7. In FIG. 13, when the discotic liquid crystal monomer is DLC-10, n in the molecular structural formula is equal to 2. The mass proportion of the discotic liquid crystal component 103 in the composite hole transport layer 101 is 20%, that is, the mass ratio of the matrix 102 to the discotic liquid crystal component 103 is equal to 8:2. The preparation process of the composite hole transport layer 101 is roughly as follows: first, dissolving the matrix monomers CBP-V and the discotic liquid crystal monomers DLC-10 in a toluene solvent at a mass ratio of 8:2 to prepare a mixed solution. Then, removing solvent, annealing, polymerization and other processes are performed under the same conditions as Embodiment 1 to form the composite hole transport layer 101. Then, sequentially forming film layers such as the light-emitting layer 106, the electron transport layer 107, the electron injection layer 108, and the second electrode layer 109 on the composite hole transport layer 101, thereby preparing a light-emitting device. An optoelectronic testing system was used to characterize the driving voltage, current efficiency, external quantum efficiency, and working lifetime of the light-emitting device of Embodiment 14. The test results are illustrated in Embodiment 14 of Table 1.

### Embodiment 15

In Embodiment 15, the materials of the first electrode layer 104, the hole injection layer 105, the light-emitting layer 106, the electron transport layer 107, the electron injection layer 108, and the second electrode layer 109 of the light-emitting device are the same as in Embodiment 1. The difference is that the composite hole transport layer 101 in Embodiment 15 is formed by cross-linking polymerization of the discotic liquid crystal monomer DLC-11 illustrated in FIG. 13 and the matrix monomer CBP-V illustrated in FIG. 7. In FIG. 13, when the discotic liquid crystal monomer is DLC-11, n in the molecular structural formula is equal to 5. The mass proportion of the discotic liquid crystal component 103 in the composite hole transport layer 101 is 20%, that is, the mass ratio of the matrix 102 to the discotic liquid crystal component 103 is equal to 8:2. The preparation process of the composite hole transport layer 101 is roughly as follows: first, dissolving the matrix monomers CBP-V and the discotic liquid crystal monomers DLC-11 in a toluene solvent at a mass ratio of 8:2 to prepare a mixed solution. Then, removing solvent, annealing, polymerization and other processes are performed under the same conditions as Embodiment 1 to form the composite hole transport layer 101. Then, sequentially forming film layers such as the light-emitting layer 106, the electron transport layer 107, the electron injection layer 108, and the second electrode layer 109 on the composite hole transport layer 101, thereby preparing a light-emitting device. An optoelectronic testing system was used to characterize the driving voltage, current efficiency, external quantum efficiency, and working lifetime of the light-emitting device in Embodiment 15. The test results are illustrated in Embodiment 15 in Table 1.

### Embodiment 16

In Embodiment 16, the materials of the first electrode layer 104, the hole injection layer 105, the light-emitting layer 106, the electron transport layer 107, the electron injection layer 108, and the second electrode layer 109 of the light-emitting device are the same as in Embodiment 1. The difference is that the composite hole transport layer 101 in Embodiment 16 is formed by cross-linking polymerization of the discotic liquid crystal monomer DLC-12 illustrated in FIG. 13 and the matrix monomer CBP-V illustrated in FIG. 7. In FIG. 13, when the discotic liquid crystal monomer is DLC-12, n in the molecular structural formula is equal to 10. The mass proportion of the discotic liquid crystal component 103 in the composite hole transport layer 101 is 20%, that is, the mass ratio of the matrix 102 to the discotic liquid crystal component 103 is equal to 8:2. The preparation process of the composite hole transport layer 101 is roughly as follows: first, dissolving the matrix monomers CBP-V and the discotic liquid crystal monomers DLC-12 in a toluene solvent at a mass ratio of 8:2 to form a mixed solution. Then, removing solvent, annealing, polymerization and other processes are performed under the same conditions as Embodiment 1 to form the composite hole transport layer 101. Then, sequentially forming film layers such as the light-emitting layer 106, the electron transport layer 107, the electron injection layer 108, and the second electrode layer 109 on the composite hole transport layer 101, thereby preparing a light-emitting device. An optoelectronic testing system was used to characterize the driving voltage, current efficiency, external quantum efficiency, and working lifetime of the light-emitting device of Embodiment 16. The test results are illustrated in Embodiment 16 of Table 1.

### Embodiment 17

In Embodiment 17, the materials of the first electrode layer 104, the hole injection layer 105, the light-emitting layer 106, the electron transport layer 107, the electron injection layer 108, and the second electrode layer 109 of the light-emitting device are the same as in Embodiment 1. The difference is that the composite hole transport layer 101 in Embodiment 17 is formed by cross-linking polymerization of the discotic liquid crystal monomer DLC-13 illustrated in FIG. 13 and the matrix monomer CBP-V illustrated in FIG. 7. In FIG. 13, when the discotic liquid crystal monomer is DLC-13, n in the molecular structural formula is equal to 15. The mass proportion of the discotic liquid crystal component 103 in the composite hole transport layer 101 is 20%, that is, the mass ratio of the matrix 102 to the discotic liquid crystal component 103 is equal to 8:2. The preparation process of the composite hole transport layer 101 is roughly as follows: first, dissolving the matrix monomers CBP-V and the discotic liquid crystal monomers DLC-13 in a toluene solvent at a mass ratio of 8:2 to prepare a mixed solution. Then, removing solvent, annealing, polymerization and other processes are performed under the same conditions as Embodiment 1 to form the composite hole transport layer 101. Then, sequentially forming film layers such as the light-emitting layer 106, the electron transport layer 107, the electron injection layer 108, and the second electrode layer 109 on the composite hole transport layer 101, thereby preparing a light-emitting device. An optoelectronic testing system was used to characterize the driving voltage, current efficiency, external quantum efficiency, and working lifetime of the light-emitting device of Embodiment 17. The test results are illustrated in Embodiment 17 of Table 1.

### Embodiment 18

In Embodiment 18, the materials of the first electrode layer 104, the hole injection layer 105, the light-emitting layer 106, the electron transport layer 107, the electron injection layer 108, and the second electrode layer 109 of the light-emitting device are the same as in Embodiment 1. The difference is that the composite hole transport layer 101 in Embodiment 18 is formed by cross-linking polymerization of the discotic liquid crystal monomer DLC-14 illustrated in FIG. 13 and the matrix monomer CBP-V illustrated in FIG. 7. In FIG. 13, when the discotic liquid crystal monomer is DLC-14, n in the molecular structural formula is equal to 20. The mass proportion of the discotic liquid crystal component 103 in the composite hole transport layer 101 is 20%, that is, the mass ratio of the matrix 102 to the discotic liquid crystal component 103 is equal to 8:2. The preparation process of the composite hole transport layer 101 is roughly as follows: first, dissolving the matrix monomers CBP-V and the discotic liquid crystal monomers DLC-14 in a toluene solvent at a mass ratio of 8:2 to prepare a mixed solution. Then, removing solvent, annealing, polymerization and other processes are performed under the same conditions as Embodiment 1 to form the composite hole transport layer 101. Then, sequentially forming film layers such as the light-emitting layer 106, the electron transport layer 107, the electron injection layer 108, and the second electrode layer 109 on the composite hole transport layer 101, thereby preparing a light-emitting device. An optoelectronic testing system was used to characterize the driving voltage, current efficiency, external quantum efficiency, and working lifetime of the light-emitting device of Embodiment 18. The test results are illustrated in Embodiment 18 of Table 1.

TABLE 1
Electro-optical parameters of light-emitting devices

| | | | External | |
|---|---|---|---|---|
| | | Current | Quantum | Working |
| | Driving | Effi- | Effi- | Lifetime |
| Device | Voltage | ciency(cd/A) | ciency(EQE) | (LT50) |
| Embodiment 1 | 100% | 100% | 100% | 100% |
| Embodiment 2 | 95% | 125% | 126% | 280% |
| Embodiment 3 | 85% | 165% | 170% | 360% |
| Embodiment 4 | 92% | 147% | 147% | 320% |
| Embodiment 5 | 93% | 140% | 138% | 300% |
| Embodiment 6 | 88% | 140% | 135% | 270% |
| Embodiment 7 | 86% | 160% | 165% | 350% |
| Embodiment 8 | 85% | 164% | 168% | 355% |
| Embodiment 9 | 88% | 155% | 160% | 330% |
| Embodiment 10 | 90% | 145% | 140% | 280% |
| Embodiment 11 | 93% | 136% | 124% | 230% |
| Embodiment 12 | 96% | 120% | 116% | 160% |
| Embodiment 13 | 98% | 108% | 105% | 140% |
| Embodiment 14 | 90% | 145% | 150% | 310% |
| Embodiment 15 | 92% | 135% | 135% | 260% |
| Embodiment 16 | 93% | 122% | 120% | 200% |
| Embodiment 17 | 94% | 112% | 108% | 140% |
| Embodiment 18 | 97% | 103% | 102% | 120% |

Note:
LT50 (Life Time to 50% output) in Table 1 refers to the time required for the output power of the light-emitting device to reduce to 50% of the rated output power within the set effective working range. This value reflects the aging degree of the light-emitting device.

It can be seen from the data in Table 1 that the light-emitting device of Embodiment 3 has the highest current efficiency, the highest external quantum efficiency, and the longest working lifetime. In the light-emitting device of Embodiment 3, the matrix monomer constituting the matrix 102 in the composite hole transport layer 101 is CBP-V, the discotic liquid crystal monomer constituting the discotic liquid crystal component 103 in the composite hole transport layer 101 is DLC-1. On the one hand, from the perspective of doping ratio, the mass proportion of the discotic liquid crystal component 103 in the composite hole transport layer 101 is 20%. This doping ratio is a relatively optimal doping ratio. When the mass proportion of the discotic liquid crystal component 103 in the composite hole transport layer 101 is less than 20%, the content of liquid crystal molecules is relatively small, the carrier mobility of the composite hole transport layer 101 will be affected; when the mass proportion of the discotic liquid crystal component 103 in the composite hole transport layer 101 is greater than 20%, the film uniformity of the composite hole transport layer 101 becomes worse, which affects the potential barrier at the interface of the functional layer, thereby causing the carrier transport to become worse. When the mass proportion of the discotic liquid crystal component 103 in the composite hole transport layer 101 is 20%, the composite hole transport layer 101 can have both high carrier mobility and good film uniformity. By increasing the hole mobility of the composite hole transport layer 101, the balance between the hole mobility and the electron mobility of the light-emitting device can be promoted, and the charge injection and transport capabilities can be improved. On the other hand, from the perspective of the molecular structure of the discotic liquid crystal monomer DLC-1, as illustrated in FIG. 6, the substituent group R8 is a flexible alkoxy chain with 5 carbon atoms, the chain length is moderate, making the discotic liquid crystal monomer DLC-1 have both a rigid core and flexible side chains, which can ensure the high hole mobility and polymerization performance of the discotic liquid crystal monomer DLC-1; the polymerizable functional group R9 is a thermally polymerizable functional group, and the two polymerizable functional groups R9 are located at two distant substitution positions of the discotic liquid crystal monomer DLC-1, which is beneficial to cross-linking polymerization.

In addition, it should be noted that compared to the hole transport layer of OLED devices, discotic liquid crystal molecules are more suitable for the hole transport layer of QLED devices, because the hole mobility of the hole transport layer used in OLED devices is usually significantly higher than the electron mobility of the electron transport layer, there is no need to introduce additional discotic liquid crystal molecules to further improve the hole mobility of the hole transport layer. In contrast, the electron transport layer of QLED devices usually uses metal oxides with high mobility such as ZnO. The hole mobility of the hole transport layer of QLED devices is significantly lower than the electron mobility of the electron transport layer. In order to achieve charge balance, it is necessary to use hole transport materials with higher mobility. For example, as in the present application, discotic liquid crystal component with high hole mobility is introduced to improve the hole mobility of the composite hole transport layer, which promotes the balance of hole mobility and electron mobility of QLED devices, improves charge injection and transport capabilities, and significantly improves the overall efficiency and lifetime of QLED devices. In addition, the molecular weight of discotic liquid crystal components is usually relatively large and has flexible alkyl chains or alkoxy chains, which makes the thermal stability of the discotic liquid crystal component not particularly high, so it is not suitable for the evaporation process of OLED devices, but it is suitable for the solution process of QLED devices.

In addition, although the introduction of discotic liquid crystal molecules into organic solar cells has been reported, it needs to be emphasized that the technical fields of QLED devices and organic solar cells are far apart, and the role of discotic liquid crystal molecules in organic solar cells is completely different from that in QLED devices. For example, in terms of phase state, the discotic liquid crystal molecules in QLED devices need to be cross-linked in a stable polymer film layer to ensure the amorphous state of the composite film, thereby enhancing the stability of the QLED device during operation; however the discotic liquid crystal molecules in organic solar cells can exist individually in the form of self-assembled molecules, and as an interface layer between charge transport and active layers, there are no strict requirements for the phase state of the discotic liquid crystal molecules. For another example, from the perspective of the function of layers, the discotic liquid crystal molecules in the QLED device are doped into the matrix to serve as an effective component of the composite hole transport layer, thereby improving the hole mobility of the composite hole transport layer and making the carriers in the QLED device tend to be balanced; however the discotic liquid crystal molecules in organic solar cells serve as the interface layer between the hole transport layer and the organic active layer to improve the defects at the bottom of the organic active layer and the mobility of carriers, and promote charge carrier extraction. For yet another example, from the perspective of molecular orientation characteristics, the discotic liquid crystal monomers in QLED devices form micro-pillars perpendicular to the device through self-assembly, thereby promoting carrier transport; however, the discotic liquid crystal monomers in organic solar cells form micro-pillars perpendicular to the device and micro-pillars parallel to the device through self-assembly. Micropillars with two orientations exist at the same time and form a three-dimensional transmission channel with the photovoltaic microcrystalline material to promote the extraction of carriers.

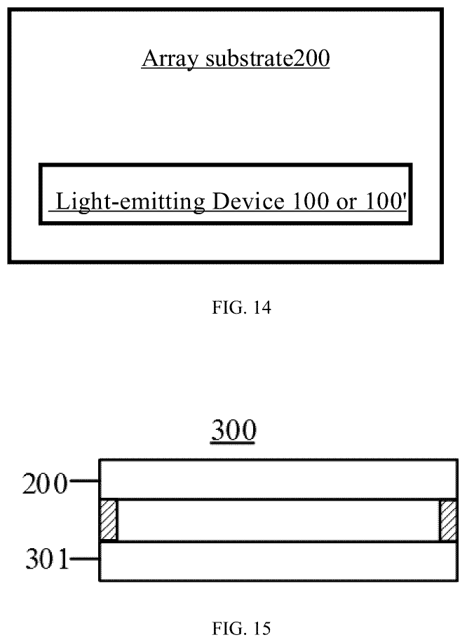

FIG. 14 illustrates a block diagram of an array substrate 200 according to another embodiment of the present disclosure. The array substrate 200 may comprise a plurality of light-emitting devices 100 or 100′ described in any of the previous embodiments, the material and molecular structure of the discotic liquid crystal component 103 of the composite hole transport layer 101 in the light-emitting device 100 or 100′ and the mass ratio of the discotic liquid crystal component 103 to the matrix 102 may be as described in the previous embodiments, and will not be described again here.

The array substrate 200 may have substantially the same technical effect as the light-emitting device 100 or 100′ described in the previous embodiment, and therefore, for the purpose of brevity, the description will not be repeated here.

FIG. 15 illustrates a schematic structural diagram of a display device 300 according to another embodiment of the present disclosure. The display device 300 comprises: the array substrate 200 described according to the previous embodiment, the array substrate 200 may comprise a plurality of light-emitting devices 100 or 100′ described in any of the previous embodiments; and an opposing substrate 301 opposite to the array substrate 200. The display device 300 may be a mobile phone, a tablet computer, a television, a monitor, a notebook computer, a digital photo frame, a navigator, or any other product or component with a display function. In some embodiments, display device 300 is a quantum dot light emitting diode display device. Compared with traditional organic light-emitting diode display devices, quantum dot light-emitting diode display devices have better color purity, better contrast and stronger stability.

The display device 300 may have substantially the same technical effect as the light-emitting device 100 or 100′ described in the previous embodiment, and therefore, for the purpose of brevity, the description will not be repeated here.

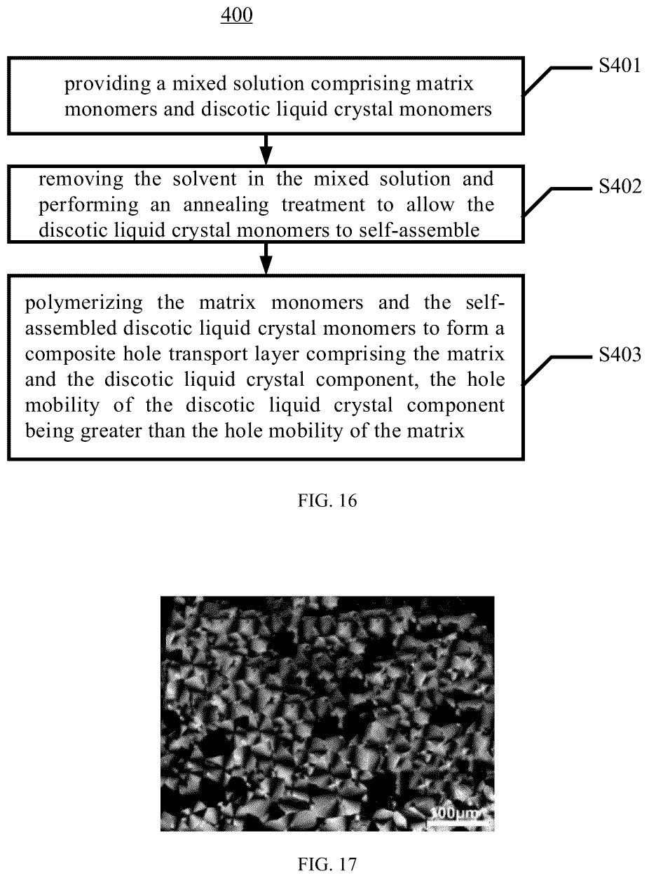

FIG. 16 illustrates a flowchart of a method 400 of preparing a light-emitting device according to another embodiment of the present disclosure. In the following, method 400 is described with reference to FIG. 16.

S401: providing a mixed solution comprising matrix monomers and discotic liquid crystal monomers.

The discotic liquid crystal monomers may have the general structural formula illustrated in FIG. 3, and the matrix monomers may have the general structural formula illustrated in FIG. 4.

S402: removing the solvent in the mixed solution and performing an annealing treatment to allow the discotic liquid crystal monomers to self-assemble.

For example, under specific temperature conditions, the solvent in the mixed solution slowly evaporates until it is removed, and the discotic liquid crystal monomers self-assemble to form ordered columnar structures. The columnar structures are embedded in matrix monomers with good film-forming properties, thereby building a molecular channel with higher hole mobility.

S403: polymerizing the matrix monomers and the self-assembled discotic liquid crystal monomers to form a composite hole transport layer comprising the matrix and the discotic liquid crystal component, the hole mobility of the discotic liquid crystal component being greater than the hole mobility of the matrix.

For example, the matrix monomers and the self-assembled discotic liquid crystal monomers may be cross-linked and polymerized through a UV polymerization process or a thermal polymerization process, the formed composite hole transport layer has both the good film-forming properties of the matrix and the high mobility properties of the discotic liquid crystal component. In some embodiments, the hole mobility of the discotic liquid crystal component 103 is 10⁻³˜10⁻² cm²V⁻¹s⁻¹, and the hole mobility of the matrix 102 is 10⁻⁶˜10⁻³ cm²V⁻¹s⁻¹.

The molecular structure of the matrix monomer is generally a molecular structure with a rigid core, while the molecular structure of the discotic liquid crystal monomer has a rigid discoid core and a certain number or proportion of flexible chains. Discotic liquid crystal monomers need to be self-assembled and formed into an orderly molecular stacking form under specific processing conditions, thereby improving their own mobility. If the matrix monomers and the discotic liquid crystal monomers are mixed directly without any treatment, the two molecular systems will be doped with each other and polymerize directly, causing the hole transport characteristics and film-forming properties of the matrix monomers and the high hole mobility characteristics formed by the self-assembly of the discotic liquid crystal monomers to be seriously affected, and the overall hole transport effect will become worse. In contrast, in the method 400 provided by the embodiment of the present disclosure, after the matrix monomers and the discotic liquid crystal monomers are mixed, the mixed solution is heat treated, under specific temperature conditions, the solvent in the mixed solution slowly evaporates until it is removed. The discotic liquid crystal monomers self-assemble to form columnar structures with high mobility and are embedded in the matrix monomers with good film-forming properties. The matrix monomers and the discotic liquid crystal monomers are polymerized and solidified through a polymerization process, so the composite hole transport layer formed has both the good film-forming properties of the matrix monomer and the high mobility properties of the discotic liquid crystal monomer.

In some embodiments, step S403 of polymerizing the matrix monomers and the self-assembled discotic liquid crystal monomers to form a composite hole transport layer comprising the matrix and discotic liquid crystal components comprises the following sub-steps: irradiating the matrix monomers and the self-assembled discotic liquid crystal monomers with ultraviolet light, so that the matrix monomers and the self-assembled discotic liquid crystal monomers undergo UV polymerization to form a composite hole transport layer. Specifically, at least one of the polymerizable functional group R10 of the matrix monomer and the polymerizable functional group R9 of the discotic liquid crystal monomer is a UV polymerizable functional group, and the ultraviolet polymerizable functional group contains at least one difunctional monomer. Under the control of the solvent or its own concentration, applying a mixed solution of the matrix monomers and the discotic liquid crystal monomers to the surface of the hole injection layer 105 away from the first electrode layer 104 using a process such as coating or inkjet printing, removing the solvent in the mixed solution to form a uniform film. Annealing in a specific temperature range, such as 80˜100° C., to self-assemble the discotic liquid crystal monomers. Then under specific UV irradiation conditions, for example, the UV irradiation intensity is 2.0˜10.0 mW/cm² and the UV irradiation time is 2.0˜15.0 minutes, the monomers with polymerizable functional groups are polymerized and cross-linked in the entire material system, to form a composite hole transport layer.

In some embodiments, step S403 of polymerizing the matrix monomers and the self-assembled discotic liquid crystal monomers to form a composite hole transport layer comprising the matrix and discotic liquid crystal components comprises the following sub-steps: heating the matrix monomers and the self-assembled discotic liquid crystal monomers to thermally polymerize the matrix monomers and the self-assembled discotic liquid crystal monomers to form a composite hole transport layer. Specifically, at least one of the polymerizable functional group R10 of the matrix monomer and the polymerizable functional group R9 of the discotic liquid crystal monomer is a thermally polymerizable functional group, and the thermally polymerizable functional group contains at least one difunctional monomer. Under the control of the solvent or its own concentration, applying a mixed solution of the matrix monomers and the discotic liquid crystal monomers to the surface of the hole injection layer away from the first electrode layer 104 using a process such as coating or inkjet printing, removing the solvent in the mixed solution to form a uniform film. Annealing in a specific temperature range, such as 80˜100° C. to self-assemble the discotic liquid crystal monomers. Then at a specific temperature, such as a temperature of 180 to 260° C., thermal polymerization takes about 0.5 to 1.5 hours, and the monomers with polymerizable functional groups are polymerized and cross-linked in the entire material system to form a composite hole transport layer.

FIG. 17 illustrates the photo of the composite hole transport layer film under a polarizing microscope before annealing. It can be seen from FIG. 17 that the discotic liquid crystal monomers in this case has a typical focal cone-like texture, which indicates that the discotic liquid crystal monomer has poor orientation and disordered arrangement before annealing.

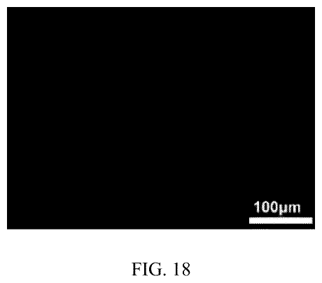

FIG. 18 illustrates the photo of the composite hole transport layer film under a polarizing microscope after annealing. After annealing treatment, the discotic liquid crystal monomers self-assemble into a columnar arrangement in an ordered manner with good molecular orientation, thus forming a dark field.

In some embodiments, referring to FIG. 5A, the method 400 may further comprise: forming the first electrode layer 104; forming the hole injection layer 105 on the first electrode layer 104; coating the mixed solution of the matrix monomers and the discotic liquid crystal monomers formed in step S401 on the side of the hole injection layer 105 away from the first electrode layer 104, and then performing steps S402 and S403 to form the composite hole transport layer 101; forming the light-emitting layer 106 on the side of the composite hole transport layer 101 away from the first electrode layer 104; forming the electron transport layer 107 on the side of the light-emitting layer 106 away from the first electrode layer 104; forming the electron injection layer 108 on the side of the electron transport layer 107 away from the first electrode layer 104; and forming a second electrode layer 109 on the side of the electron injection layer 108 away from the first electrode layer 104.

In some alternative embodiments, referring to FIG. 5B, method 400 may further comprise: forming a second electrode layer 109; forming an electron injection layer 108 on the second electrode layer 109; forming the electron transport layer 107 on the side of the electron injection layer 108 away from the second electrode layer 109; forming the light-emitting layer 106 on the side of the electron transport layer 107 away from the second electrode layer 109; coating the mixed solution of the matrix monomers and the discotic liquid crystal monomers formed in step S401 on the side of the light-emitting layer 106 away from the second electrode layer 109, and then performing steps S402 and S403 to form the composite hole transport layer 101; forming the hole injection layer 105 on the side of the composite hole transport layer 101 away from the second electrode layer 109; and forming the first electrode layer 104 on the side of the hole injection layer 105 away from the second electrode layer 109.

In an embodiment, the material of the first electrode layer 104 may be ITO, and the material of the hole injection layer 105 may be PEDOT:PSS, the light-emitting layer 106 may be blue quantum dots, the light-emitting peak of the blue quantum dots luminescent layer may be 455˜465 nm, and the wavelength range corresponds to deep blue light. The material of the electron transport layer 107 may be ZnO, and the material of the electron injection layer 108 may be polyvinylpyrrolidone. The material of the second electrode layer 109 may be Al, and the composite hole transport layer 101 may be formed by cross-linking polymerization of the discotic liquid crystal monomer DLC-1 illustrated in FIG. 6 and the matrix monomer CBP-V illustrated in FIG. 7. The structural formula of the composite hole transport layer 101 is illustrated in FIG. 8, in which the mass proportion of the discotic liquid crystal component 103 in the composite hole transport layer 101 is 20%. The preparation process of the composite hole transport layer 101 is roughly as follows: the matrix monomers CBP-V and the discotic liquid crystal monomers DLC-1 are dissolved in the toluene solvent at a mass ratio of 8:2 to prepare a mixed solution. The mixed solution is then coated on the surface of the hole injection layer 105 away from the first electrode layer 104. At a first temperature (for example, 120° C.), the solvent in the mixed solution is gradually evaporated until it is removed, and annealing is performed within a first period of time (for example, 0.5 hours). The self-assembly of the discotic liquid crystal monomers DLC-1 is completed. The matrix monomers and the self-assembled discotic liquid crystal monomers are then heated at a second temperature (e.g., 240° C.) for about a second period of time (e.g., 1.5 hours). The discotic liquid crystal monomers DLC-1 and the matrix monomers CBP-V are thermally polymerized and cross-linked to form a uniform polymer film, thereby forming the composite hole transport layer 101.

The mass proportion of the discotic liquid crystal component 103 in the composite hole transport layer 101 is 20%, and this doping ratio is a relatively optimal doping ratio. When the mass proportion of the discotic liquid crystal component 103 in the composite hole transport layer 101 is less than 20%, the content of liquid crystal molecules is relatively small, and the carrier mobility of the composite hole transport layer 101 will be affected; when the mass proportion of the discotic liquid crystal component 103 in the composite hole transport layer 101 is greater than 20%, the film uniformity of the composite hole transport layer 101 becomes worse, which affects the potential barrier at the interface of the functional layer, thereby causing the carrier transport to become worse. When the mass proportion of the discotic liquid crystal component 103 in the composite hole transport layer 101 is 20%, the composite hole transport layer 101 can have both high carrier mobility and good film uniformity. By increasing the hole mobility of the composite hole transport layer 101, the balance between the hole mobility and the electron mobility of the light-emitting device can be promoted, and the charge injection and transport capabilities can be improved. The light-emitting device in this embodiment corresponds to the light-emitting device in Embodiment 3 of Table 1, and its driving voltage, current efficiency, external quantum efficiency, and working lifetime can refer to the values listed in Embodiment 3 of Table 1.

It will be understood that although the terms first, second, third, etc. may be used herein to describe various elements, compositions, regions, layers and/or portions, these elements, compositions, regions, layers and/or portions should not be limited by these terms. These terms are only used to distinguish an element, composition, region, layer or portion from another element, composition, region, layer or portion. Thus, a first element, composition, region, layer or portion discussed above could be termed a second element, composition, region, layer or portion without departing from the teachings of the present disclosure.

Spatially relative terms such as “row”, “column”, “below”, “above”, “left”, “right”, etc. may be used herein for ease of description to describe factors such as the relationship of an element or feature to another element(s) or feature(s) illustrated in the figures. It will be understood that these spatially relative terms are intended to encompass different orientations of the device in use or operation in addition to the orientation depicted in the figures. For example, if the device in the figures is turned over, elements described as “below” other elements or features would then be oriented “above” other elements or features. Thus, the exemplary term “below” can encompass both an orientation of above and below. The device may be otherwise oriented (rotated 90 degrees or at other orientations) and the spatially relative descriptors used herein are interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to limit the present disclosure. As used herein, the singular forms “a,” “an,” and “the” are intended to comprise the plural forms as well, unless the context clearly dictates otherwise. It will be further understood that the terms “comprise” and/or “include” when used in this specification designate the presence of stated features, integers, steps, operations, elements and/or parts, but do not exclude the presence or addition of one or more other features, integers, steps, operations, elements, compositions and/or groups thereof. As used herein, the term “and/or” comprises any and all combinations of one or more of the associated listed items. In the description of this specification, description with reference to the terms “an embodiment,” “another embodiment,” etc. means that a particular feature, structure, material, or characteristic described in connection with the embodiment is included in at least one embodiment of the present disclosure. In this specification, schematic representations of the above terms are not necessarily directed to the same embodiment or example. Furthermore, the particular features, structures, materials or characteristics described may be combined in any suitable manner in any one or more embodiments or examples. Furthermore, those skilled in the art may combine the different embodiments or examples as well as the features of the different embodiments or examples described in this specification without conflicting each other.

It will be understood that when an element or layer is referred to as being “on”, “connected to”, “coupled to”, or “adjacent to” another element or layer, it may be directly on, directly connected to, directly coupled to, or directly adjacent to another element or layer, or intervening elements or layers may be present. In contrast, when an element is referred to as being “directly on”, “directly connected to”, “directly coupled to”, “directly adjacent to” another element or layer, with no intervening elements or layers present. However, in no case should “on” or “directly on” be interpreted as requiring a layer to completely cover the layer below.

Embodiments of the disclosure are described herein with reference to schematic illustrations (and intermediate structures) of idealized embodiments of the disclosure. As such, variations to the shapes of the illustrations are to be expected, e.g., as a result of manufacturing techniques and/or tolerances. Accordingly, embodiments of the present disclosure should not be construed as limited to the particular shapes of the regions illustrated herein, but are to comprise deviations in shapes due, for example, to manufacturing. Thus, the regions illustrated in the figures are schematic in nature and their shapes are not intended to illustrate the actual shape of a region of a device and are not intended to limit the scope of the present disclosure.

Unless otherwise defined, all terms (comprising technical and scientific terms) used herein have the same meaning as commonly understood by one of ordinary skill in the art to which this disclosure belongs. It will be further understood that terms such as those defined in commonly used dictionaries should be construed to have meanings consistent with their meanings in the relevant art and/or the context of this specification, and will not be idealized or overly interpreted in a formal sense, unless expressly defined as such herein.

As will be appreciated by those skilled in the art, although the steps of the methods of the present disclosure are depicted in a particular order in the figures, this does not require or imply that the steps must be performed in that particular order, unless the context clearly dictates otherwise. Additionally or alternatively, multiple steps may be combined into one step for execution, and/or one step may be decomposed into multiple steps for execution. Furthermore, other method steps may be inserted between the steps. The inserted steps may represent such as improvements of a method described herein, or may be unrelated to the method. Also, a given step may not be fully complete before the next step starts.

The above descriptions are merely specific embodiments of the present disclosure, but the protection scope of the present disclosure is not limited thereto. Any changes or substitutions that those skilled in the art can easily think of within the technical scope disclosed by the present disclosure, should be comprised within the protection scope of the present disclosure. Therefore, the protection scope of the present disclosure should be based on the protection scope of the claims.

1. A light-emitting device comprising a composite hole transport layer, wherein the composite hole transport layer comprises a matrix and a discotic liquid crystal composition, a hole mobility of the discotic liquid crystal composition is greater than a hole mobility of the matrix.

2. The light-emitting device according to claim 1, wherein a hole mobility of the composite hole transport layer is 10⁻⁴˜10⁻³ cm²V⁻¹s⁻¹.

3. The light-emitting device according to claim 1, wherein an energy level of a highest occupied molecular orbital of the composite hole transport layer is −6.0˜−5.3 eV.

4. The light-emitting device according to claim 1, wherein a mass proportion of the discotic liquid crystal composition in the composite hole transport layer is 1%˜40%.

5. (canceled)

6. The light-emitting device according to claim 1, wherein a general structural formula of the composite hole transport layer is: 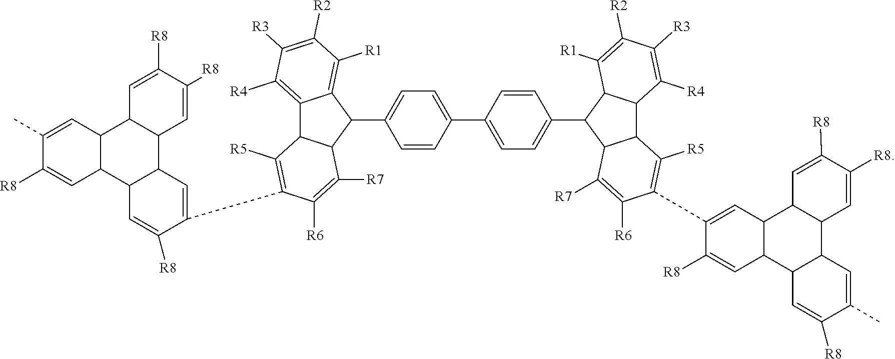
wherein R8 comprises any one of an alkyl chain, an alkoxy chain, or an alkyl ester chain, R8 at different positions of the general structural formula of the composite hole transport layer are same or different, and each of R1, R2, R3, R4, R5, R6, and R7 comprises any one of a benzene ring, a double bond, a cyclohexane, or a hydrogen atom.

7. The light-emitting device according to claim 6, wherein the discotic liquid crystal composition is formed from discotic liquid crystal monomers, and a general structural formula of the discotic liquid crystal monomers is: 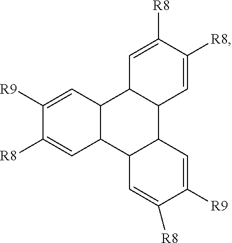
wherein R9 is a polymerizable functional group and comprises any one of a tert-butyl ethyl ester, an olefinic bond, an acrylate, a vinyl ether, a thiol, and or an epoxy.

8. The light-emitting device according to claim 7, wherein R8 is a flexible alkyl chain having 4˜6 carbon atoms.

9. (canceled)

10. The light-emitting device according to claim 1, wherein the matrix is configured to cause holes to migrate in an orderly manner in the composite hole transport layer under an action of an electric field.

11. The light-emitting device according to claim 10, wherein the matrix is formed of matrix monomers, and a general structural formula of the matrix monomers is: 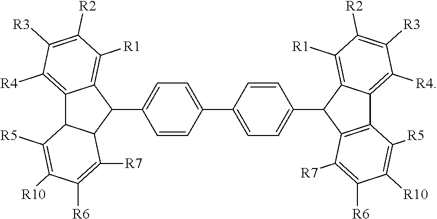
wherein R10 is a polymerizable functional group and comprises any one of an olefinic bond, an acrylate, a vinyl ether, a thiol, and or an epoxy.

12. The light-emitting device according to claim 11, wherein each of R1, R2, R3, R4, R5, R6, and R7 is a hydrogen atom, R10 is the olefinic bond, R8 is an alkoxy chain, and R9 is a tert-butyl ethyl ester.

13. The light-emitting device according to claim 11, wherein at least one of R9 or R10 is an ultraviolet polymerizable functional group, and the ultraviolet polymerizable functional group comprises at least a difunctional monomer; or
wherein at least one of R9 or R10 is a thermally polymerizable functional group, and the thermally polymerizable functional group comprises at least a difunctional monomer.

14. (canceled)

15. The light-emitting device according to claim 1, wherein the discotic liquid crystal compositions are arranged as columnar structures in an ordered manner in the composite hole transport layer, a height direction of a respective one of the columnar structures is parallel to a thickness direction of the composite hole transport layer, and the matrix is at least arranged among the columnar structures.

16. The light-emitting device according to claim 1, wherein the hole mobility of the discotic liquid crystal composition is 10⁻³˜10⁻² cm²V⁻¹s⁻¹, wherein an energy level of a highest occupied molecular orbital of the discotic liquid crystal composition is −6.5˜−5.5 eV, and an energy level of a lowest unoccupied molecular orbital of the discotic liquid crystal composition is −3.0˜−1.8 eV.

17. (canceled)

18. The light-emitting device according to claim 1, further comprising:
a first electrode layer;
a hole injection layer between the first electrode layer and the composite hole transport layer;
a light-emitting layer on a side of the composite hole transport layer away from the first electrode layer;
an electron transport layer on a side of the light-emitting layer away from the first electrode layer;
an electron injection layer on a side of the electron transport layer away from the first electrode layer; and
a second electrode layer on a side of the electron injection layer away from the first electrode layer.

19. The light-emitting device according to claim 18, wherein the light-emitting layer comprises a quantum dot configured to emit blue light.

20. The light-emitting device according to claim 19, wherein a material of the first electrode layer is indium tin oxide, a material of the hole injection layer is poly(3,4-ethylenedioxythiophene): polystyrene sulfonate, a material of the electron transport layer is zinc oxide, a material of the electron injection layer is polyvinylpyrrolidone, a material of the second electrode layer is aluminum, a wavelength of the blue light emitted by the light-emitting layer is 455˜465 nm, a mass proportion of the discotic liquid crystal composition in the composite hole transport layer is 20%, a mass proportion of the matrix in the composite hole transport layer is 80%, and a structural formula of the composite hole transport layer is:

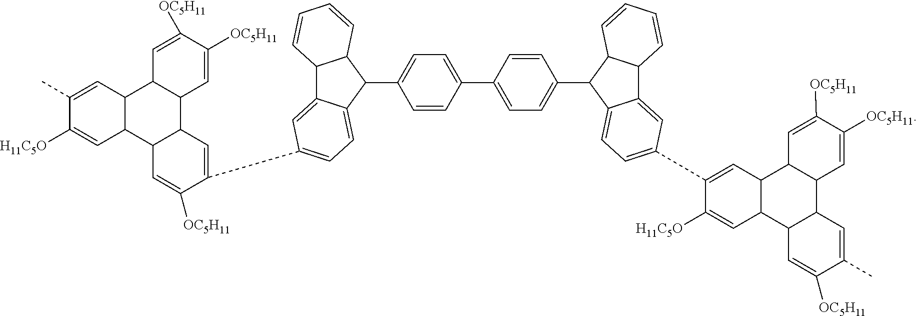

21. The light-emitting device according to claim 18, wherein the light-emitting layer comprises a quantum dot configured to emit red light, a mass proportion of the discotic liquid crystal composition in the composite hole transport layer is 25%˜30%, and a wavelength of the red light is 620˜640 nm.

22. The light-emitting device according to claim 18, wherein the light-emitting layer comprises a quantum dot configured to emit green light, a mass proportion of the discotic liquid crystal composition in the composite hole transport layer is 20%˜25%, and a wavelength of the green light is 525˜535 nm.

23. A display device comprising a plurality of light-emitting devices according to claim 1.

24. A method of preparing a light-emitting device, comprising:
providing a mixed solution comprising matrix monomers and discotic liquid crystal monomers;
removing a solvent of the mixed solution and performing an annealing treatment to allow the discotic liquid crystal monomers to self-assemble; and
polymerizing the matrix monomers and self-assembled discotic liquid crystal monomers to form a composite hole transport layer comprising a matrix and a discotic liquid crystal composition, a hole mobility of the discotic liquid crystal composition being greater than a hole mobility of the matrix.

25. (canceled)

26. (canceled)

27. (canceled)

28. (canceled)

29. (canceled)
